(19) United States
(12) Patent Application Publication
(10) Pub. No.: US 2026/0162574 A1
(43) Pub. Date: Jun. 11, 2026

(54) DISPLAY DEVICE AND METHOD OF TESTING THE SAME

(71) Applicant: Samsung Display Co., Ltd., Yongin-si (KR)

(72) Inventors: Hye Jung HONG, Yongin-si (KR); Jae Ho CHOI, Yongin-si (KR); Joo Woan CHO, Yongin-si (KR); Byeong Hwa CHOI, Yongin-si (KR); Hae Yun CHOI, Yongin-si (KR)

(21) Appl. No.: 19/179,791

(22) Filed: Apr. 15, 2025

(30) Foreign Application Priority Data
Jun. 26, 2024 (KR) 10-2024-0083709
Jul. 26, 2024 (KR) 10-2024-0099440

(51) Int. Cl. G09G 3/00; G01R 31/28; G09G 3/3233; G09G 3/3275

(52) U.S. Cl. CPC G09G 3/006; G01R 31/2825; G09G 3/3233; G09G 3/3275; G09G 2300/0452; G09G 2310/0289; G09G 2330/021; G09G 2330/10; G09G 2330/12

(57) ABSTRACT

A display device according to one or more embodiments includes a pixel in a display area, and including a pixel driver connected between a first power line, which is configured to receive a first voltage, and a first node, and including a driving transistor, a light-emitting element connected between a second power line, which is configured to receive a second voltage that is different from the first voltage, and the first node, and a switch element connected between the first node and a current detection terminal, and configured to be turned on in response to a test control signal supplied during a test period.

### CROSS-REFERENCE TO RELATED APPLICATION

The present application claims priority to, and the benefit of, Korean Patent Application No. 10-2024-0083709, filed on Jun. 26, 2024, and Korean Patent Application No. 10-2024-0099440, filed on Jul. 26, 2024, in the Korean Intellectual Property Office, the entire disclosures of which are incorporated herein by reference.

### BACKGROUND

### 1. Field

Embodiments of the present disclosure relate to a display device and a method of testing the same.

### 2. Description of the Related Art

With the advance of information-oriented society, more and more demands are placed on display devices for displaying images in various ways. Along with this trend, various types of display devices including a light-emitting display device are being developed. A light-emitting display device includes a pixel including a light-emitting element.

### SUMMARY

Aspects of the present disclosure provide a display device capable of detecting a current flowing through a light-emitting element and a method of testing the same.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including a pixel in a display area, and including a pixel driver connected between a first power line, which is configured to receive a first voltage, and a first node, and including a driving transistor, a light-emitting element connected between a second power line, which is configured to receive a second voltage that is different from the first voltage, and the first node, and a switch element connected between the first node and a current detection terminal, and configured to be turned on in response to a test control signal supplied during a test period.

The pixel driver may include transistors connected in series between the first power line and the first node, and including the driving transistor, wherein the switch element is directly connected to the first node.

The display device may further include a backplane layer including the pixel driver, the switch element, and a pixel electrode connected to the pixel driver and to the switch element at the first node, and a light-emitting element layer above the backplane layer, and including the light-emitting element.

The light-emitting element may be commonly connected to the pixel driver and to the switch element through the pixel electrode.

The display device may include a first pixel, a second pixel, and a third pixel, which include respective pixel drivers, respective light-emitting elements, and respective switch elements, and respectively emit light of a first color, light of a second color, and light of a third color.

The light-emitting elements of the first pixel, the second pixel, and the third pixel are at a same layer within the light-emitting element layer.

The light-emitting elements of the first pixel, the second pixel, and the third pixel may be at different respective layers within the light-emitting element layer.

The display device may further include a display driver configured to supply driving signals to the pixel during a display period, which is for displaying an image corresponding to input image data in the display area, and during the test period, and a test controller configured to supply the test control signal to the switch element during the test period.

The display driver may include a data driver configured to supply digital data, which corresponds to input image data or test image data, to the pixel during the display period and the test period, and a clock generator configured to supply a clock signal to the pixel during the display period and the test period.

The pixel driver may include a pulse generator connected to a gate electrode of the driving transistor to generate a pulse signal corresponding to the digital data, wherein the driving transistor is configured to supply a current to the first node in response to the pulse signal.

The display driver may further include a current controller configured to supply a bias signal to the pixel.

The pixel driver may further include a bias transistor connected in series with the driving transistor between the first power line and the first node, and configured to adjust the current in response to the bias signal.

The bias transistor may include a first bias transistor connected between the driving transistor and the first node, and configured to control the current in response to a first bias signal supplied from the current controller, and a second bias transistor connected between the first bias transistor and the first node, and configured to control the current in response to a second bias signal supplied from the current controller.

The display device may further include pixels in the display area, and including the pixel, a first pixel configured to emit light of a first color, a second pixel configured to emit light of a second color, and a third pixel configured to emit light of a third color.

The current controller may be configured to supply a same first bias signal to respective first bias transistors of the first pixel, the second pixel, and the third pixel, and is configured to supply different respective second bias signals to respective second bias transistors of the first pixel, the second pixel, and the third pixel.

According to an aspect of the present disclosure, there is provided a method of testing a display device including a pixel including a pixel driver, a light-emitting element, and a switch element commonly connected to a first node, the method including supplying driving signals and a test control signal to the pixel during a test period in which a test mode is executed, and detecting a current flowing through the first node through the switch element turned on by the test control signal.

The switch element may be directly connected to the first node, wherein the current flowing through the first node is directly detected through the switch element.

The method may further include determining whether the pixel is defective based on the current.

The display device may include pixels including respective pixel drivers, respective light-emitting elements, and respective switch elements, wherein, during the test period, the respective switch elements are concurrently turned on, and respective currents flowing through respective first nodes of the pixels are concurrently detected.

The display device may include pixels including respective pixel drivers, respective light-emitting elements, and respective switch elements, wherein, during the test period, the respective switch elements of the pixels are sequentially turned on, and respective currents flowing through respective first nodes of the pixels are sequentially detected.

According to an aspect of the present disclosure, there is provided an electronic device including a display device including a pixel in a display area, and including a pixel driver connected between a first power line, which is configured to receive a first voltage, and a first node, and including a driving transistor, a light-emitting element connected between a second power line, which is configured to receive a second voltage that is different from the first voltage, and the first node, and a switch element connected between the first node and a current detection terminal, and configured to be turned on in response to a test control signal supplied during a test period.

The electronic device may include a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, a head-mounted display (HMD), a virtual reality (VR) device, or an augmented reality (AR) device.

According to the display device and the method of testing the same according to embodiments, a current flowing through a pixel during a test period may be detected through a switch element directly connected to a first node between a pixel driver and the light-emitting element. Accordingly, the reliability of the test may be increased and the yield of the display device may be improved.

However, aspects according to the embodiments of the present disclosure are not limited to those described above and various other aspects are incorporated herein.

### BRIEF DESCRIPTION OF THE DRAWINGS

The above and other aspects of the present disclosure will become more apparent by describing in detail embodiments thereof with reference to the attached drawings, in which:

FIG. 1 is a perspective view illustrating a display device according to one or more embodiments;

FIG. 2 is a block diagram illustrating a display device according to one or more embodiments;

FIG. 3 is a diagram showing a pixel according to one or more embodiments;

FIG. 4 is a diagram illustrating a method of driving a pixel in a display mode according to one or more embodiments;

FIG. 5 is a diagram illustrating a method of driving a pixel in a test mode according to one or more embodiments;

FIG. 6 is a flowchart illustrating a method of testing a display device according to one or more embodiments;

FIG. 7 is a plan view illustrating a display area of a display device according to one or more embodiments;

FIG. 8 is a cross-sectional view illustrating a display panel according to one or more embodiments;

FIG. 9 is a cross-sectional view illustrating a display panel according to one or more embodiments;

FIG. 10 is a diagram illustrating a smart watch including a display device according to one or more embodiments;

FIGS. 11 and 12 illustrate a head-mounted display including a display device according to one or more embodiments;

FIG. 13 illustrates a head-mounted display including a display device according to one or more embodiments;

FIG. 14 is a diagram illustrating a dashboard of an automobile and a center fascia including display devices according to one or more embodiments; and

FIG. 15 is a diagram illustrating a transparent display device including a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing one or more embodiments corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

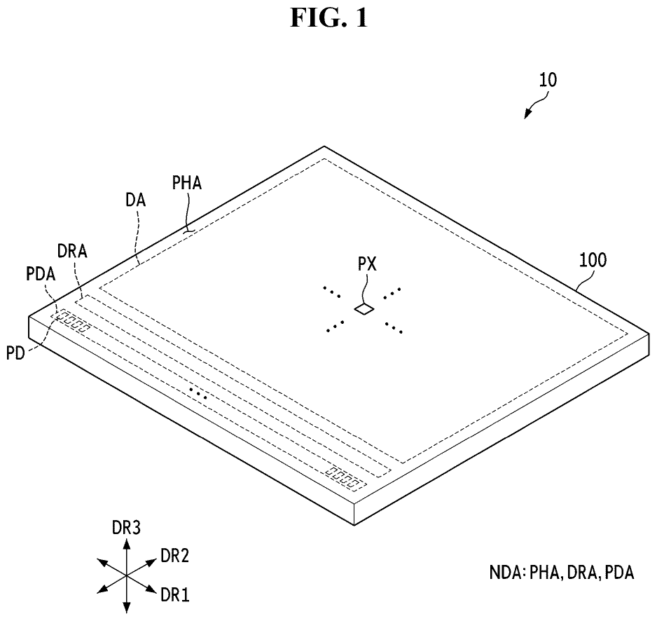

FIG. 1 is a perspective view illustrating a display device according to one or more embodiments.

Referring to FIG. 1, a display device 10 is a device for displaying a moving image or a still image, and may be used as a display screen for various products. For example, the display device 10 may be used as a display screen for various electronic devices such as televisions, laptop computers, monitors, billboards and the Internet of Things (IOT) as well as portable electronic devices such as mobile phones, smart phones, tablet personal computers (tablet PCs), smart watches, watch phones, mobile communication terminals, electronic notebooks, electronic books, portable multimedia players (PMPs), navigation systems, and ultra mobile PCs (UMPCs). Additionally, the display device 10 may be applied to electronic devices such as a virtual reality (VR) device, an augmented reality (AR) device, or the like. The display device 10 according to embodiments disclosed hereinafter may be included in various electronic devices, including at least one of the electronic devices described above.

In one or more embodiments, the display device 10 may be a light-emitting display device including light-emitting elements. For example, the display device 10 may be a light-emitting display device such as an organic light-emitting display including an organic light-emitting diode, a quantum dot light-emitting display including a quantum dot light-emitting layer, an inorganic light-emitting display including an inorganic semiconductor, or an ultra-small light-emitting display using an ultra-small light-emitting diode such as a micro light-emitting diode (micro LED) or a nano light-emitting diode (nano LED).

Hereinafter, embodiments are disclosed in which the display device 10 is a light-emitting display device including a micro light-emitting diode (micro LED) or a nano light-emitting diode (nano LED). However, the type or size of the light-emitting element according to embodiments is not limited thereto.

The display device 10 may include a display panel 100 including a display area DA and a non-display area NDA. In one or more embodiments, the display panel 100 may have a quadrilateral planar shape, but is not limited thereto. For example, the display panel 100 may have a polygonal shape other than a quadrilateral shape, a circular shape, an elliptical shape, or an irregular shape in plan view. In FIG. 1, a first direction DR1, a second direction DR2, and a third direction DR3 are indicated. In one or more embodiments, the first direction DR1, the second direction DR2, and the third direction DR3 may be the horizontal direction, the vertical direction, and the thickness direction of the display panel 100, respectively.

The display area DA may be an area in which pixels PX are located, and may be an area in which an image is displayed by the pixels PX. For example, the pixels PX and wires (or some of the wires) connected to the pixels PX may be located in the display area DA. In describing embodiments, the term “connect” may include electrical connection and/or physical connection. Although FIG. 1 illustrates one or more embodiments in which the planar shape of the display area DA is quadrilateral, the shape of the display area DA is not limited thereto.

Each of the pixels PX may emit light of a corresponding color. For example, each of the pixels PX may emit red light, blue light, green light, white light, or light of another color.

In one or more embodiments, each of the pixels PX may include a light-emitting element. For example, each of the pixels PX may include a light-emitting element that emits red light, blue light, green light, white light, or light of another color.

In one or more embodiments, each of the pixels PX may include the light-emitting element that emits light of a color matching the emission color of the pixel PX. In one or more other embodiments, at least one pixel PX may include the light-emitting element that emits light of a different color from the emission color of the pixel PX, and a light conversion layer that converts the color or the wavelength of light emitted from the light-emitting element may be located on the light-emitting element (as used herein, “located on” may mean “above”).

In one or more embodiments, the light-emitting element of each of the pixels PX may be a light-emitting diode (LED). For example, each of the pixels PX may include a micro light-emitting diode (micro LED) or a nano light-emitting diode (nano LED) having a size in the order of micrometers or nanometers. For example, the light-emitting element may be a micro light-emitting diode having a horizontal length, a vertical length, a diameter, or a height, each of them being several hundred micrometers, or more narrowly, about 100 micrometers or less, but is not limited thereto. The light-emitting element may emit light having a peak wavelength in a corresponding wavelength band. For example, the light-emitting element may emit light having a peak wavelength in the red wavelength band, the green wavelength band, or the blue wavelength band.

In one or more embodiments, each of the pixels PX may further include a pixel circuit electrically connected to the light-emitting element. Each pixel circuit may supply a driving current to the light-emitting element in response to driving signals supplied to the pixel PX. The pixel circuit may include circuit elements, such as transistors. In one or more embodiments, the pixel circuit may be located or formed within a semiconductor circuit substrate implemented by a semiconductor stacked structure on a substrate.

The non-display area NDA may be an area where an image is not displayed. The non-display area NDA may be located around the display area DA. In one example, the non-display area NDA may be located at the edge of the display panel 100 to surround the display area DA.

The non-display area NDA may include a pad area PDA and a peripheral area PHA. In one or more embodiments, the non-display area NDA may further include a driving circuit area DRA located around the display area DA (e.g., in plan view, and/or between the display area DA and the pad area PDA).

The pads PD may be located in the pad area PDA. The pads PD may be connected to an external circuit board. For example, the pads PD may be electrically connected to circuit pads on the circuit board through a conductive connection member, such as a wire. Additionally, the pads PD may also be electrically connected to the pixels PX and a display driver. For example, the pads PD may include signal pads and power pads electrically connected to the pixels PX and the display driver. In one or more embodiments, the pixels PX and the pads PD may be electrically connected to each other through circuit elements and/or wires formed on a semiconductor circuit board or the like of the display panel 100. Through the pads PD, driving signals and driving voltages for driving the pixels PX may be supplied from the external circuit board to the display panel 100. When the display panel 100 includes at least a portion of the display driver, driving signals and driving voltages for driving the display driver may be supplied to the display panel 100 from an external circuit board through the pads PD.

At least a portion of the display driver may be located in the driving circuit area DRA. For example, the display driver that generates driving signals for the pixels PX may be located in the driving circuit area DRA.

The peripheral area PHA may be the remaining area of the non-display area NDA excluding the pad area PDA and the driving circuit area DRA. The peripheral area PHA may surround the display area DA. The wires connecting the display driver and/or the pads PD to the pixels PX may pass through the peripheral area PHA.

In one or more embodiments, the peripheral area PHA may include a common voltage supply area. For example, a common electrode located in the display area DA may extend to the peripheral area PHA and may be connected to a power line that transmits a common voltage (e.g., a second voltage supplied to the pixels PX) in the peripheral area PHA.

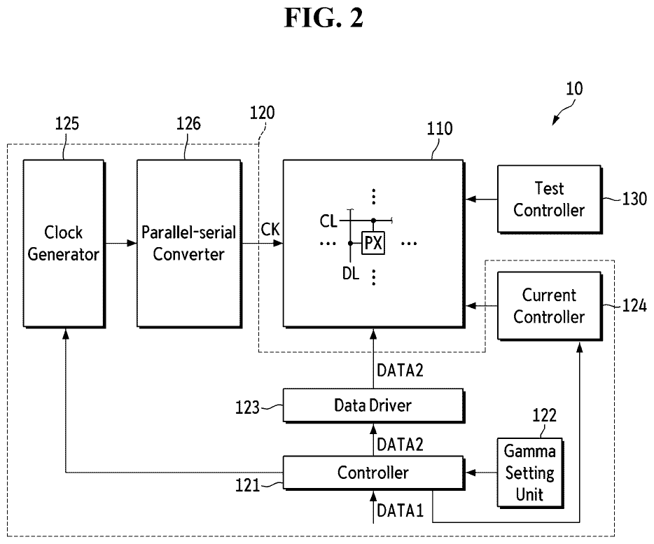

FIG. 2 is a block diagram illustrating a display device according to one or more embodiments.

Referring to FIG. 2, the display device 10 may include a display (e.g., a display unit) 110 and a display driver 120. In one or more embodiments, the display device 10 may further include a test controller 130.

The display 110 may be located inside the display panel of the display device 10, for example, the display panel 100 of FIG. 1. For example, the display 110 may be located in the display area DA of the display panel 100. The display 110 may include the pixels PX. The display 110 may display an image by the pixels PX.

The pixels PX may be connected to signal lines and power lines to which respective driving signals and driving voltages are applied. In one or more embodiments, the signal lines connected to the pixels PX may include clock lines CL (or scan lines) and data lines DL. In one or more embodiments, each of the pixels PX may receive a clock signal CK from a clock generator 125 (or a parallel-serial converter 126) through each of the clock lines CL, and may receive digital data DATA2 from a data driver 123 through each of the data lines DL. Each of the pixels PX may emit light in the form corresponding to the clock signal CK and the digital data DATA2. For example, each of the pixels PX may emit light with a luminance corresponding to each of the clock signal CK and the digital data DATA2 during each frame or each subframe. In one or more embodiments, the power lines connected to the pixels PX may include a first power line to which a first voltage (e.g., a high-potential pixel voltage) is applied, and a second power line to which a second voltage (e.g., a low-potential pixel voltage) is applied. However, the embodiments are not limited thereto. For example, the types, numbers, or the like of the signal lines and the power lines connected to the pixels PX may be changed according to the structure and/or the driving method of the pixels PX.

Hereinafter, one or more embodiments is disclosed in which the pixels PX of the display 110 are driven in a pulse width modulation (hereinafter referred to as “PWM”) method in response to the digital data DATA2. In one or more embodiments, the display 110 may display an image by using the digital data DATA2 of n bits, which may display 2ⁿ grayscales.

The pixel PX may operate on a frame-by-frame basis. Each frame may include a data write period and an emission period. During the data write period, a certain number of bits (e.g., n bits) of the digital data DATA2 may be applied to and stored in the pixel PX. During the emission period, the digital data DATA2 stored in the pixel PX is read in synchronization with the clock signal CK, and the digital data DATA2 may be converted into a PWM signal. Accordingly, the pixel PX may express a grayscale corresponding to the digital data DATA2.

In one or more embodiments, one frame may include a plurality of subframes. Even in this case, each subframe may include a data write period and an emission period, and the emission period of the subframe may be the sum of the time allocated to each bit of the digital data DATA2.

The display driver 120 may drive and control the display 110. The display driver 120 may include a controller 121, a game setter (e.g., a gamma-setting unit) 122, the data driver 123, a current controller 124, and the clock generator 125.

The controller (e.g., a “control unit”) 121 may receive input image data DATA1 of one frame from an external source (e.g., a graphic controller), receive a correction value from the gamma setter 122, perform gamma correction on the input image data DATA1 by using the correction value, and thus generate correction image data. The controller 121 may extract grayscale for each of the pixels PX from the correction image data of one frame and may convert the extracted grayscale into the digital data DATA2 of a number of bits (e.g., predetermined number of bits), for example, the digital data DATA2 of n bits.

The controller 121 may output the converted digital data DATA2 to the data driver 123. The duration of one frame (e.g., the length of one frame) may correspond to the sum of the time allocated to each bit of the digital data DATA2. The time allocated to each bit may be the same or different.

The gamma setter 122 may set a gamma value by using a gamma curve, may set a correction value for the input image data DATA1 by the set gamma value, and may output the set correction value to the controller 121. The gamma setter 122 may be provided as a separate circuit from the controller 121, or may be included within the controller 121.

The data driver 123 may receive the digital data DATA2 (e.g., the digital data DATA2 of n bits) from the controller 121 in units of frames, and may transmit the digital data DATA2 to each of the pixels PX of the display 110. The data driver 123 may include a line buffer and shift register circuit. A line buffer may be a 1-line buffer or a 2-line buffer. The data driver 123 may supply the digital data DATA2 to each of the pixels PX for each frame on a line basis (on a row basis).

In one or more embodiments, the data driver 123 may supply the digital data DATA2 corresponding to the input image data DATA1 to each of the pixels PX during a display period in which a display mode is executed. Additionally, the data driver 123 may supply the digital data DATA2 corresponding to the test image data to each of the pixels PX during a test period in which a test mode is executed. Accordingly, during the display period, a driving current corresponding to the input image data DATA1 may flow through the pixels PX, and during the test period, a test current corresponding to the test image data may flow through the pixels PX.

The current controller 124 may generate a bias signal for adjusting a current (e.g., a driving current or a test current) flowing through the pixels PX of the display 110. For example, the current controller 124 may adjust the current flowing the pixels PX by supplying the bias signal to the pixels PX of the display 110. For example, the current controller 124 may be connected to at least one bias transistor included in each of the pixels PX and may control or adjust the current flowing through the bias transistor by applying a bias signal to the bias transistor. The magnitudes of the currents flowing through the pixels PX may be controlled by the current controller 124. In one or more embodiments, the current controller 124 may configure a bias transistor and a current mirror included in each of the pixels PX.

The current controller 124 may be shared among a plurality of pixels PX. For example, the current controller 124 (or each current control circuit included in the current controller 124) may be shared by all the pixels PX of the display 110 or by at least the pixels PX of one color. The current controller 124 may be electrically connected to the bias transistor of each of the plurality of pixels PX to configure a current mirror circuit.

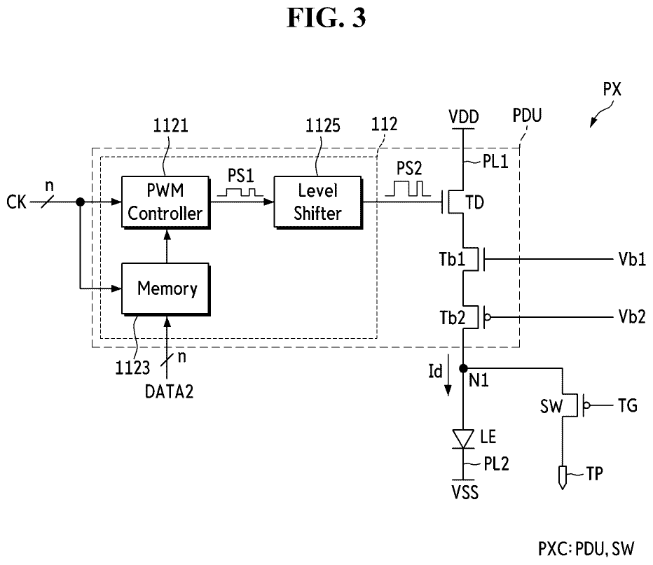

In one or more embodiments, each of the pixels PX may include a first bias transistor (e.g., a first bias transistor Tb1 of FIG. 3) and a second bias transistor (e.g., a second bias transistor Tb2 of FIG. 3) connected in series with each other on a path through which a driving current flows. The current controller 124 may include a first current control circuit connected to the first bias transistors Tb1 of all the pixels PX of the display 110, and second current control circuits respectively connected to the second bias transistors Tb2 of the pixels PX of a corresponding color of the display 110. The reference current of all the pixels PX may be primarily controlled by the first current control circuit, and the reference currents flowing through the pixels PX of a corresponding color may be additionally controlled or optimized by the respective second current control circuits. A driving current (or test current) corresponding to a reference current adjusted by the first bias transistor and the second bias transistor may flow through each of the pixels PX. The driving currents flowing through the pixels PX of each color may be differentiated or optimized according to the characteristics of the pixels PX emitting light of different colors by the second current control circuits.

For example, the reference current flowing through all the pixels PX of the display 110 may be concurrently or substantially simultaneously changed or controlled by the first current control circuit. In addition, the reference current flowing through the pixels PX (e.g., red pixels, green pixels, and blue pixels) of a corresponding color of the display 110 may be individually changed or controlled by each second current control circuit. For example, the same second bias signal may be applied to the gate electrode of the second bias transistor included in each of the pixels PX emitting a corresponding color (e.g., red, green, or blue) by one second current control circuit, and the reference current flowing through the pixels PX of the corresponding color may be changed according to the second bias signal.

The clock generator 125 may generate a plurality of clock signals CK during one frame, and may output them to the pixels PX. The operation of a pixel driver (e.g., a pixel-driving part) included in each of the pixels PX may be controlled by the clock signals CK.

In one or more embodiments, the clock generator 125 may generate n clock signals CK during one frame, and may output them to the pixels PX. The clock generator 125 may sequentially supply n clock signals CK to the clock lines CL of the display 110 for each frame. The n clock signals CK may be output corresponding to the digital data DATA2 of n bits. The signal width (e.g., a pulse width or a length of a gate-on voltage) of each clock signal CK may be determined according to the time allocated to each bit of the digital data DATA2.

In one or more embodiments, the display driver 120 may further include the parallel-serial converter 126 connected between the clock generator 125 and the display 110. The parallel-serial converter 126 may convert n clock signals CK generated in parallel in the clock generator 125 into serial signals, and may output the converted serial signals to the respective clock lines CL. In one or more embodiments, the parallel-serial converter 126 may include a logic circuit including an OR gate. The parallel-serial converter 126 may be formed separately from the clock generator 125, or may be formed inside the clock generator 125.

The components of the display driver 120 may be formed as separate integrated circuits, respectively, or may be formed as a single integrated circuit chip. All components of the display driver 120, or some of the components of the display driver 120 may be formed or mounted directly on the substrate of the display panel 100 on which the display 110 is formed, may be attached or connected on the display panel 100 by being mounted on a flexible printed circuit film or the like, or may be attached to the substrate in the form of a tape carrier package (TCP) or the like. In one or more embodiments, the controller 121, the gamma setter 122, and the data driver 123 may be connected to the display 110 in the form of an integrated circuit chip, and the current controller 124, the clock generator 125, and the parallel-serial converter 126 may be formed directly on the substrate of the display panel 100 (e.g., within the semiconductor circuit substrate of the display panel 100).

The test controller 130 may drive and control the display 110 in the form corresponding to the test mode. For example, the test controller 130 may supply a test control signal (e.g., a test scan signal) to the pixels PX during the test period in which the test mode is executed. In one or more embodiments, each of the pixels PX may include a switch element (e.g., a test transistor that is turned on in the test mode) that is turned on in response to the test control signal. The switch element may be connected between a corresponding node of each of the pixels PX and a current detection terminal (or a current detection circuit). In one or more embodiments, the switch elements included in the plurality of pixels PX (e.g., the pixels PX positioned in a corresponding area or block, at least one row, or at least one column of the display 110) may share one current detection terminal. For example, one end of the switch elements included in the plurality of pixels PX may be connected to a corresponding node of each of the plurality of pixels PX, and the other end of the switch elements may be commonly connected to one current detection terminal. The current detection terminal may be connected to a test circuit or test device. The current detected through the current detection terminal may be used to determine the defect of the pixels PX.

The test controller 130 may concurrently or substantially simultaneously supply test control signals to the switch elements connected to one current detection terminal, or may supply the test control signals sequentially or individually to the switch elements. When the test control signals are concurrently or substantially simultaneously supplied to the switch elements, a current corresponding to the sum of the currents flowing through the pixels PX including the switch elements may be detected. When the test control signals are sequentially or individually supplied to the switch elements, the currents flowing through the pixels PX including the switch elements may be sequentially or individually detected. By controlling or changing at least one of the respective test control signals supplied to the switch elements of the pixels PX or the connection structure between the switch elements and the current detection terminal, the currents flowing through the pixels PX may be detected in a desired manner (e.g., concurrently or substantially simultaneously, by group, or individually).

The test controller 130 may be located or formed inside the display panel 100, or may be provided outside the display panel 100 to be connected to the display panel 100. For example, the test controller 130 may be formed or mounted directly on the substrate of the display panel 100 on which the display 110 is formed, may be attached or connected on the display panel 100 by being mounted on a flexible printed circuit film or the like, or may be attached to the substrate in the form of a tape carrier package (TCP) or the like. Additionally, the test controller 130 may be separately formed from the display driver 120 or may be integrated into the display driver 120.

FIG. 3 is a diagram showing a pixel according to one or more embodiments. For example, FIG. 3 illustrates one or more embodiments of the pixel PX driven in a PWM method. However, embodiments are not limited thereto, and the structure, type, driving method, or the like of the pixel PX may be changed according to embodiments. In FIG. 3, some components of the pixels PX are depicted in the form of equivalent circuits, and other components of the pixels PX are depicted in the form of blocks.

Referring to FIGS. 1 to 3, the pixel PX may include a pixel circuit PXC and a light-emitting element LE. The pixel circuit PXC may include a pixel driver PDU and a switch element SW. The pixel driver PDU and the switch element SW may be electrically connected to each other through a first node N1. The light-emitting element LE may be electrically connected to the pixel circuit PXC through the first node N1.

The pixel driver PDU generates or controls a driving current Id (or a reference current) of the pixel PX corresponding to the driving signals supplied to the pixel PX. The pixel driver PDU may also referred to as “driving part” of the pixel PX. In one or more embodiments, the pixel driver PDU may include a circuit that expresses grayscale by adjusting the time at which the driving current Id flows through the light-emitting element LE in a PWM method. However, the type or structure of the pixel PX, or the operation method of the pixel PX may be variously changed depending on embodiments, and accordingly, the type, number, or the like of the driving signals supplied to the pixel PX may also vary. In the one or more embodiments corresponding to FIG. 3, the pixel driver PDU is disclosed that generates the driving current Id corresponding to the digital data DATA2 in a PWM method.

The pixel driver PDU may be connected between a first power line PL1 and the first node N1. A first voltage VDD outputted from a power supply (e.g., a power supply unit) provided inside the display panel 100 or outside the display panel 100 may be applied to the first power line PL1. The first node N1 may be a node through which the pixel driver PDU (or the pixel circuit PXC) is connected to the light-emitting element LE, for example, a common node between the pixel driver PDU and the light-emitting element LE. The pixel driver PDU generates and/or controls the driving current Id supplied to the first node N1 in response to the digital data DATA2 inputted from the data driver 123. The pixel driver PDU may also be referred to as “first pixel circuit.”

The pixel driver PDU may include at least one transistor connected between the first power line PL1 and the first node N1. For example, the pixel driver PDU may include a driving transistor TD and at least one bias transistor Tb1 or Tb2 connected in series between the first power line PL1 and the first node N1. In one or more embodiments, the bias transistors Tb1 and Tb2 may include the first bias transistor Tb1 and the second bias transistor Tb2 that control or adjust the driving current Id in response to a first bias signal Vb1 and a second bias signal Vb2, respectively.

The first bias signal Vb1 and the second bias signal Vb2 may be supplied from the current controller 124. In one or more embodiments, the first bias signal Vb1 and the second bias signal Vb2 may be different signals. For example, the first bias signal Vb1 may be a bias signal for adjusting the driving current Id of all the pixels PX located in the display area DA at once, and may be commonly supplied to all the pixels PX located in the display area DA. The second bias signal Vb2 may be a bias signal for optimizing the respective driving currents Id for each of the pixels PX of a corresponding color located in the display area DA, and may be commonly supplied to the pixels PX of a corresponding color located in the display area DA. For example, the second bias signals Vb2 of different voltages may be supplied to the pixels PX emitting light of different respective colors among the pixels PX in the display area DA.

The pixel driver PDU may further include a pulse generator 112 connected to the gate electrode of the driving transistor TD. The pulse generator 112 may generate a pulse signal corresponding to the digital data DATA2. For example, the pulse signal may be a PWM signal in the form corresponding to the digital data DATA2. The on/off of the driving transistor TD may be controlled by the PWM signal.

The pulse generator 112 may store the bit value of the digital data DATA2 of n bits applied from the data driver 123 in the data write period for each frame and may generate a PWM signal based on n bit values and the clock signal CK in the emission period. The PWM signal generated in the pulse generator 112 may be applied to the gate electrode of the driving transistor TD.

In one or more embodiments, the pulse generator 112 may include a PWM controller 1121 and a memory 1123. In one or more embodiments, the pulse generator 112 may further include a level shifter 1125.

The clock signal CK may be a serial clock signal obtained by converting n clock signals generated in parallel in the clock generator 125 into a serial signal through the parallel-serial converter 126. The parallel-serial converter 126 (or the clock generator 125) may transmit the clock signal CK to each of the PWM controller 1121 and the memory 1123 in the pulse generator 112.

The pulse generator 112 may store the bit value of the digital data DATA2 applied from the data driver 123 during the data write period for each subframe, and may generate a first PWM signal PS1 based on the bit value stored in the emission period and the clock signal CK. Additionally, the pulse generator 112 may change the level of the first PWM signal PS1 to output a second PWM signal PS2.

The PWM controller 1121 may generate the first PWM signal PS1 based on the clock signal CK inputted from the clock generator 125 and a bit value of the image data read from the memory 1123. When a clock signal is inputted from the clock generator 120, the PWM controller 1121 may read the bit value of the corresponding digital data DATA2 from the memory 1123 to generate the first PWM signal PS1.

The PWM controller 1121 may control the pulse width of the first PWM signal PS1 based on the bit value of the digital data DATA2 and the signal width of the clock signal CK on a frame basis. For example, when the bit value of the digital data DATA2 is 1, the first PWM signal PS1 having an on level (e.g., a high level) as long as the signal width of the clock signal CK may be outputted, and when the bit value of the digital data DATA2 is 0, the first PWM signal PS1 having an off level (e.g., a low level) as long as the signal width of the clock signal CK may be outputted. That is, the on time and the off time of the first PWM signal PS1 may be determined by the signal width (e.g., the pulse width) of the clock signal CK.

In one or more embodiments, the PWM controller 1121 may control the pulse output of the first PWM signal PS1 based on the time information of the edge of the clock signal CK. For example, the PWM controller 1121 may control the pulse output of the first PWM signal PS1 based on the time information of a falling edge at which the clock signal CK transitions from a high level to a low level, and a rising edge at which the clock signal CK transitions from a low level to a high level. For example, when the bit value of the digital data DATA2 is 1, the first PWM signal PS1 of the on-level may be outputted from the time point at which the edge (e.g., the rising edge) of the clock signal CK occurs until the next edge (e.g., the falling edge) occurs. Conversely, when the bit value of the digital data DATA2 is 0, the first PWM signal PS1 of the off-level may be outputted from the time point at which the edge of the clock signal CK occurs until the next edge occurs. In one or more embodiments, the PWM controller 1121 may include a logic circuit (e.g., an OR gate circuit or the like) implemented with at least one transistor.

The memory 1123 may be receive and store the digital data DATA2 of n bits applied from the data driver 123 through the data line DL during the data write period for each frame or each subframe in synchronization with a frame start signal or a subframe start signal. In a case of still images, the digital data DATA2 previously stored in the memory 1123 may be used to continuously display images for a plurality of frames before the image is updated or refreshed.

The bit value (logic level) of the digital data DATA2 may be inputted from the data driver 123 to the memory 1123 in an order (e.g., predetermined order). In one or more embodiments, the order in which the bit values of the digital data DATA2 are stored may be from the least significant bit (LSB) to the most significant bit (MSB) of a bit string. In one or more other embodiments, the order in which the bit values of the digital data DATA2 are stored may be from MSB to LSB. The memory 1123 may store at least 1 bit of data. In one or more embodiments, the memory 1123 may be an n-bit memory. In the memory 1123, n bit values of the digital data DATA2 may be written during the data write period. According to the size of the pixel PX, the driving frequency, or the like, the pixel PX may include the memory 1123 of an appropriate capacity. In one or more embodiments, the memory 1123 may be implemented with at least one transistor. The memory 1123 may be implemented as a random access memory (RAM), for example, SRAM or DRAM.

In one or more embodiments, the memory 1123 additionally stores some of the bit values of the digital data DATA2 applied and stored from the data driver 123 in response to the clock signal CK inputted from the clock generator 125 during the emission period, and the additionally stored bit values may be used for image display during at least one frame. In one or more embodiments, the additionally stored bit value may be the MSB of the digital data DATA2.

The level shifter 1125 may be connected to the output terminal of the PWM controller 1121. The level shifter 1125 may convert the voltage level of the first PWM signal PS1 outputted by the PWM controller 1121 to generate the second PWM signal PS2. The level shifter 1125 may convert the first PWM signal PS1 into the second PWM signal PS2 having a level of a gate-on voltage capable of turning on the driving transistor TD, and a level of a gate-off voltage capable of turning off the driving transistor TD. As an example, the level shifter 1125 may include a boost circuit that boosts the first PWM signal PS1 to the second PWM signal PS2.

When the first PWM signal PS1 outputted by the PWM controller 1121 has an on/off level sufficient to drive the driving transistor TD, the level shifter 1125 may be omitted. In this case, the output terminal of the PWM controller 1121 may be directly connected to the gate electrode of the driving transistor TD. Accordingly, the first PWM signal PS1 outputted by the PWM controller 1121 may be directly transmitted to the driving transistor TD.

The driving transistor TD may be connected between the first power line PL1 and the first node N1. For example, the driving transistor TD may be connected between the first power line PL1 and the first bias transistor Tb1. The gate electrode of the driving transistor TD may be connected to the pulse generator 112.

In one or more embodiments, although the driving transistor TD may be an N-type transistor, embodiments are not limited thereto. For example, the driving transistor TD may be a P-type transistor. According to the type of the driving transistor TD, the voltage of the on/off level of the PWM signal outputted from the PWM controller 1121 may vary. For example, the on-level of the PWM signal may correspond to the gate-on voltage of the driving transistor TD, and the off-level of the PWM signal may correspond to the gate-off voltage of the driving transistor TD. When the driving transistor TD is an N-type transistor, the on-level of the PWM signal may be a high-level voltage capable of turning on the driving transistor TD, and the off-level of the PWM signal may be a low-level voltage capable of turning off the driving transistor TD.

The driving transistor TD may control the current flowing through the pixel PX, for example, the driving current Id, in response to the PWM signal (e.g., the first PWM signal PS1 or the second PWM signal PS2) supplied from the pulse generator 112. For example, the driving transistor TD may be turned on/off in response to a pulse signal applied to the gate electrode, for example, the PWM signal supplied from the pulse generator 112. In embodiments, the driving transistor TD may be turned on/off in response to the PWM signal applied from the pulse generator 112 for each frame or subframe. According to the on/off of the driving transistor TD, the driving current Id may be transmitted to the light-emitting element LE, or the driving current Id may be blocked.

The time for which the driving current Id flows through the pixel PX may be controlled by the on/off period of the driving transistor TD. Additionally, the luminance of the pixel PX (e.g., luminance during each frame or subframe) may be controlled according to the time for which the driving current Id flows through the pixel PX. For example, while the driving transistor TD is turned on, the driving current Id may flow from the first power line PL1 to a second power line PL2 through the driving transistor TD, the first bias transistor Tb1, the second bias transistor Tb2, the first node N1, and the light-emitting element LE. Accordingly, the light-emitting element LE may emit light with a luminance corresponding to the driving current Id. For example, the emission time and the non-emission time of the light-emitting element LE are controlled by the turn-on time and the turn-off time of the driving transistor TD during one frame, so that the luminance of the pixel PX may be expressed. The turn-on time and turn-off time of the driving transistor TD during one frame may be determined according to the pulse width of the first PWM signal PS1.

The bias transistors Tb1 and Tb2 may include at least one transistor connected in series with the driving transistor TD on a path through which the driving current Id flows. For example, the bias transistors Tb1 and Tb2 may include the first bias transistor Tb1 and the second bias transistor Tb2 connected in series between the driving transistor TD and the first node N1.

The first bias transistor Tb1 may be connected between the driving transistor TD and the first node N1. For example, the first bias transistor Tb1 may be connected between the driving transistor TD and the second bias transistor Tb2. The gate electrode of the first bias transistor Tb1 may be connected to the current controller 124. For example, the gate electrode of the first bias transistor Tb1 may be connected to a first current control circuit included in the current controller 124 for outputting the first bias signal Vb1.

The first bias transistor Tb1 may control the driving current Id in response to the first bias signal Vb1 supplied from the current controller 124. For example, the first bias transistor Tb1 may control the magnitude of the driving current Id in response to the first bias signal Vb1.

The second bias transistor Tb2 may be connected between the first bias transistor Tb1 and the first node N1. The gate electrode of the second bias transistor Tb2 may be connected to the current controller 124. For example, the gate electrode of the second bias transistor Tb2 may be connected to a second current control circuit included in the current controller 124 for outputting the second bias signal Vb2.

The second bias transistor Tb2 may control the driving current Id in response to the second bias signal Vb2 supplied from the current controller 124. For example, the second bias transistor Tb2 may control the magnitude of the driving current Id in response to the second bias signal Vb2.

In one or more embodiments, the first bias transistor Tb1 may be an N-type transistor, and the second bias transistor Tb2 may be a P-type transistor. However, embodiments are not limited thereto, and the types of the first bias transistor Tb1 and the second bias transistor Tb2 may vary according to the embodiments.

The light-emitting element LE may be connected between the first node N1 and the second power line PL2. A second voltage VSS, which is outputted from a power supply that is provided inside the display panel 100 or outside the display panel 100, may be applied to the second power line PL2. The first voltage VDD and the second voltage VSS may be different voltages. For example, the first voltage VDD may be a high-potential driving voltage (or a high-potential pixel voltage), and the second voltage VSS may be a low-potential driving voltage (or a low-potential pixel voltage).

The light-emitting element LE may emit light in response to the driving current Id supplied from the pixel driver PDU. For example, the light-emitting element LE may emit light with a luminance corresponding to the magnitude of the driving current Id during a period in which the driving current Id is supplied from the pixel driver PDU.

In one or more embodiments, a frame may include a plurality of subframes. The light-emitting element LE may emit light or not emit light based on the bit value of the digital data DATA2 corresponding to each subframe.

The switch element SW may be connected between the first node N1 and a current detection terminal TP (e.g., a test pad). The switch element SW may also be referred to as “testing part” of the pixel PX. In one or more embodiments, the switch element SW may be directly connected to the first node N1. In describing the embodiments, “directly connected to the first node N1” may mean being directly connected to the first node N1 without going through another circuit element (e.g., another circuit element of the pixel PX). For example, one end (e.g., the source electrode of a transistor constituting the switch element SW) of the switch element SW may be directly connected to the first node N1 without going through at least one transistor constituting the pixel driver PDU. The other end (e.g., the drain electrode of the transistor constituting the switch element SW) of the switch element SW may be connected to the current detection terminal TP with or without passing through another circuit element. For example, the other end of the switch element SW may be directly connected to the current detection terminal TP, or may be connected to the current detection terminal TP through a circuit element or the like of a multiplexer circuit located outside the display 110. The control terminal of the switch element SW (e.g., the gate electrode of the transistor constituting the switch element SW) may be connected to the test controller 130.

The switch element SW may electrically connect the first node N1 of the pixel PX to the current detection terminal TP in response to a test control signal TG supplied to the pixel PX during the test period in which the test mode is executed. For example, the test controller 130 may supply the test control signal TG of a gate-on voltage (e.g., a voltage capable of turning on the switch element SW) to the switch element SW in response to the test mode, and the switch element SW may be turned on in response to the test control signal TG. The switch elements SW of the pixels PX may receive the test control signal TG of a gate-on voltage individually or in groups, and may be turned on by the test control signal TG.

When the switch element SW is turned on, the first node N1 may be connected to the current detection terminal TP. Accordingly, the current (e.g., the test current corresponding to the digital data DATA2 of a test image) flowing through the first node N1 may be introduced into the current detection terminal TP. Accordingly, the current flowing through the pixel PX may be detected at the current detection terminal TP.

In one or more embodiments, the current detection terminal TP may be one of the pads PD located in the pad area PDA, but embodiments are not limited thereto. For example, when a current detection circuit is formed or located inside the display panel 100 or on the display panel 100, the current detection terminal TP may be an input terminal of the current detection circuit.

In one or more embodiments, one current detection terminal TP may be connected to one pixel PX or the plurality of pixels PX. For example, the display panel 100 may include the current detection terminals TP individually connected to each of the pixels PX, may include a plurality of current detection terminals TP connected to the pixels PX of different groups, or may include one current detection terminal TP commonly connected to all the pixels PX. In one or more embodiments, the pixels PX of the display 110 may be distinguished by respective groups, and each group may be connected to one current detection terminal TP. The switch elements SW included in the pixels PX connected to the respective current detection terminals TP may be turned on concurrently or substantially simultaneously or sequentially. By adjusting the operating time point of the switch elements SW included in the pixels PX, the connection structure between the switch elements SW and the current detection terminals TP, or the like, the number or unit of the pixels PX of which current may be concurrently or substantially simultaneously detected may be controlled.

In one or more embodiments, the switch elements SW of the pixels PX located in each row of the display area DA may share one test control wire (e.g., a wire to which the gate electrode of the switch element SW is connected in FIG. 3) and may concurrently or substantially simultaneously receive the test control signal TG of a gate-on voltage from the test controller 130 through the test control wire. In addition, the switch elements SW of the pixels PX located in each column of the display area DA may share one current detection terminal TP, and the switch elements SW of the pixels PX located in different columns of the display area DA may be connected to the different current detection terminals TP. Accordingly, the current (e.g., test current) flowing through each of the pixels PX may be individually detected in response to the test mode. For example, while the test controller 130 is driven to sequentially supply the test control signal TG to the rows of the display area DA, the current introduced into each of the current detection terminals TP may be detected. Accordingly, the current flowing through each of the pixels PX may be individually detected, and whether each of the pixels PX is defective may be determined based on the detected current.

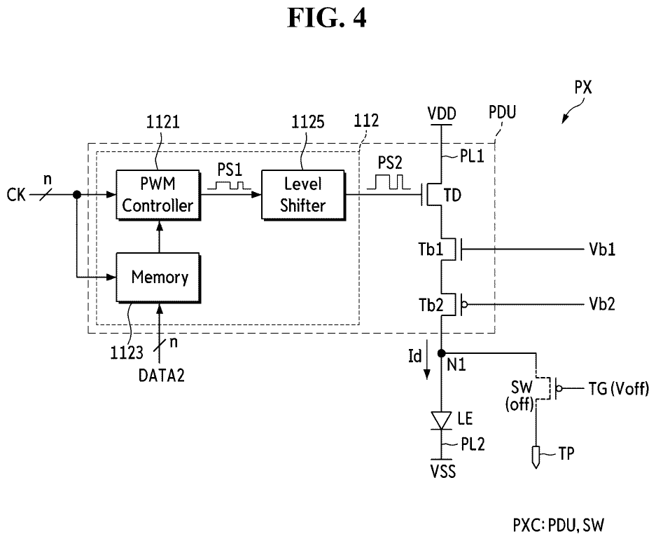

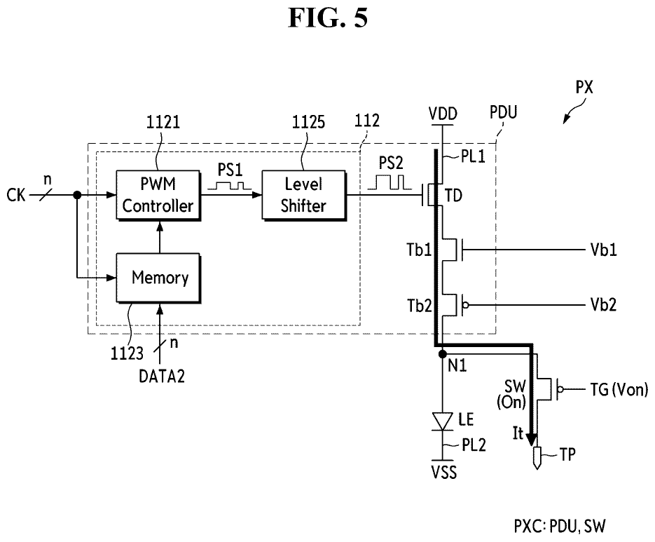

FIG. 4 is a diagram illustrating a method of driving a pixel in a display mode according to one or more embodiments. FIG. 5 is a diagram illustrating a method of driving a pixel in a test mode according to one or more embodiments. For example, FIGS. 4 and 5 illustrate the methods of driving the pixel PX of FIG. 3 in response to the display mode and the test mode, respectively.

In addition to FIGS. 1 to 3, referring to FIGS. 4 and 5, the display device 10 may be driven in different manners in response to the display mode (e.g., the normal mode) and the test mode. For example, the display device 10 may display an image corresponding to the input image data DATA1 in the display area DA during the display period, and may output currents flowing through the pixels PX through at least one current detection terminal TP, for example, the plurality of current detection terminals TP respectively connected to the plurality of pixels PX, during the test period in which the test mode is executed.

In one or more embodiments, during the display period, the display driver 120 may supply the driving signals (e.g., the digital data DATA2, the clock signals CK, the first bias signal Vb1, and the second bias signal Vb2) corresponding to the input image data DATA1 to the pixels PX. Accordingly, the driving current Id corresponding to the input image data DATA1 may be generated in the pixel driver PDU of each of the pixels PX. During the display period, the test controller 130 may supply the test control signal TG of a gate-off voltage Voff to the switch element SW of each of the pixels PX. Accordingly, as illustrated in FIG. 4, the switch element SW of each of the pixels PX may be maintained in an off state, and the driving current Id may flow through the light-emitting element LE. The light-emitting element LE may emit light with a luminance corresponding to the driving current Id during each frame or subframe of the display period. Accordingly, an image corresponding to the input image data DATA1 may be displayed in the display area DA during the display period.

In one or more embodiments, during the test period, the display driver 120 may supply the driving signals (e.g., the digital data DATA2 corresponding to the test image data, the clock signals CK, the first bias signal Vb1, and the second bias signal Vb2) corresponding to the test image data to the pixels PX. Accordingly, a test current “It” corresponding to the test image data may be generated in the pixel driver PDU of each of the pixels PX. In one or more embodiments, the test image data may be stored within the display driver 120, or may be inputted to the display driver 120 from the outside. Additionally, during the test period, the test controller 130 may supply the test control signal TG of a gate-on voltage Von to the switch element SW of each of the pixels PX. Accordingly, as illustrated in FIG. 5, the switch element SW of each of the pixels PX may be turned on, and the test current It flowing through each of the pixels PX may flow into the current detection terminal TP through the switch element SW. For example, the test current It may be introduced into the current detection terminal TP from the first power line PL1, sequentially through the driving transistor TD, the first bias transistor Tb1, the second bias transistor Tb2, the first node N1, and the switch element SW. During the test period, the light-emitting element LE may emit light or may not emit light.

In one or more embodiments, the pixels PX of the display area DA may be distinguished into a plurality of groups, and the test control signal TG of the gate-on voltage Von may be concurrently or substantially simultaneously supplied to the pixels PX of each group. In this case, the control terminals (e.g., the gate electrodes) of the switch elements SW included in the pixels PX of each group may be electrically connected to each other. Accordingly, the number of wires located on the display panel 100 may be reduced, and the efficiency of the test may be increased. Additionally, the pixels PX of each group may be connected to the different current detection terminals TP, or at least some of the pixels PX of each group may be commonly connected to one current detection terminal TP. The connection form between the test control wires (e.g., the test control wires connected between the test controller 130 and the switch elements SW to transmit each of the test control signals TG) connected to the pixels PX and the current detection terminals TP, the driving time point of the switch elements SW, or the like may be variously changed depending on embodiments. For example, the test current It flowing through the pixels PX may be appropriately detected for each pixel, block, or panel.

The test current It (e.g., the test current It flowing through at least one pixel PX or the plurality of pixels PX) detected through each of the current detection terminals TP may be used to determine a defect in the pixels PX.

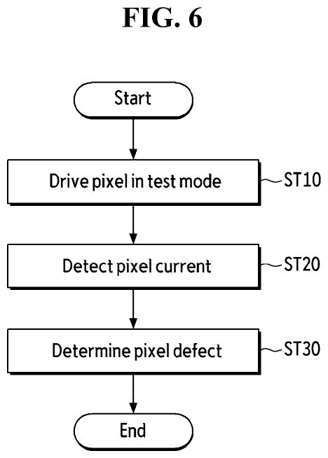

FIG. 6 is a flowchart illustrating a method of testing a display device according to one or more embodiments. For example, FIG. 6 illustrates the method of testing the current (e.g., the test current It of FIG. 5) flowing through the pixels PX of the display device 10 in response to the test mode, and determining a defect in the display device 10 based on the detected current.

Referring to FIGS. 1 to 6, first, the pixel PX may be driven in the test mode (operation ST10). For example, during the test period, the driving signals corresponding to the test image data may be supplied to each of the pixels PX, and the test control signal TG of the gate-on voltage Von may be supplied to the switch element SW of each of the pixels PX to turn on the switch element SW. Accordingly, the test current It corresponding to the test image data may be generated in the pixel driver PDU, and the test current It may be introduced into the current detection terminal TP through the first node N1 and the switch element SW. The switch elements SW provided in each of the plurality of pixels PX may be substantially concurrently or substantially simultaneously or sequentially turned on. Accordingly, the test current It flowing through each of the plurality of pixels PX may be substantially concurrently or substantially simultaneously or sequentially introduced into each of the current detection terminals TP. In addition, the test current It flowing through each of the plurality of pixels PX may be introduced into one current detection terminal TP (e.g., the current detection terminal TP shared by the pixels PX) in a summed form, or may be individually introduced into each of the current detection terminals TP.

Afterwards, the current of the pixel PX introduced into the current detection terminal TP may be detected (operation ST20). For example, the test current It flowing through the first node N1 of each of the pixels PX may be detected through the switch element SW turned on by the test control signal TG. In embodiments, the switch element SW may be directly connected to the first node N1 of each of the pixels PX, and thus, the current flowing through the first node N1 of each of the pixels PX may be directly detected through the switch element SW. According to the driving method of the pixels PX corresponding to the test mode, each of the test currents It flowing through the first nodes N1 of a plurality of pixels PX including at least some of the pixels PX may be concurrently or substantially simultaneously or sequentially detected. Additionally, the test current It flowing through each of the plurality of pixels PX may be detected in a summed form or individually.

Although FIG. 6 illustrates that an operation of driving the pixel PX in the test mode (operation ST10) and an operation of detecting the current of the pixel PX (operation ST20) are sequentially performed, embodiments are not limited thereto. For example, the operation ST10 of driving the pixel PX in the test mode and the operation ST20 of detecting the current of the pixel PX may be substantially concurrently or substantially simultaneously performed. For example, while the plurality of pixels PX is driven in the test mode, the test current It flowing through the plurality of pixels PX may be detected in real time.

Thereafter, the defect of the pixel PX may be determined (or decided) based on the detected test current It. For example, the current variation of the pixels PX may be checked by comparing the test current It (e.g., the test current It flowing through one pixel PX or the plurality of pixels PX) detected through each of the current detection terminals TP with a reference value. Accordingly, a defect in the pixels PX and the display device 10 including the same may be determined (operation ST30).

In one or more embodiments, when a defective pixel that may cause an image quality defect, such as a bright spot or a dark spot, of the display device 10 is detected, subsequent processing, such as the repair of the defective pixel, or the calibration that sets a correction value to compensate for a luminance deviation (e.g., a difference between a luminance value of the defective pixel and a reference luminance value) of the defective pixel, may be performed. Accordingly, the likelihood of a defect, such as a bright spot or a dark spot of the display device 10, may be reduced or prevented, and the yield of the display device 10 may be improved.

As described above, the pixel PX of the display device 10 according to embodiments may include the pixel driver PDU, the light-emitting element LE, and the switch element SW commonly connected to the first node N1. During the test period in which the display device 10 is driven in the test mode, driving signals (e.g., driving signals corresponding to the test image data) may be supplied to the pixel driver PDU of each of the pixels PX, and the test control signal TG (e.g., the test control signal TG of the gate-on voltage Von), which may turn on the switch element SW, may be supplied to the switch element SW. Accordingly, the test current It flowing through each of the pixels PX may be introduced into the current detection terminal TP through the transistors of the pixel driver PDU, the first node N1, and the switch element SW. In one or more embodiments, the test current It may flow through all the transistors (e.g., the driving transistor TD and the first and second bias transistors Tb1 and Tb2) of the pixel driver PDU located on the current path through which the driving current Id of each of the pixels PX flows, and the first node N1.

According to embodiments, the current flowing through the first node N1 connecting the pixel circuit PXC to the light-emitting element LE may be appropriately or effectively detected. For example, it is possible to directly detect the test current It introduced into the first node N1 through all of the transistors of the pixel driver PDU that are located on the current path of the driving current Id flowing from the first power line PL1 to the light-emitting element LE. Accordingly, it is possible to more accurately detect whether the pixel PX is defective. As a result, the defect (e.g., a bright spot or a dark spot) of the display device 10 due to the defect in the pixels PX may be more accurately detected, and the yield of the display device 10 may be improved.

Meanwhile, although the above-described embodiments disclose embodiments in which the pixels PX respectively includes the switch elements SW, the embodiments are not limited thereto. For example, at least two pixels PX may share one switch element SW.

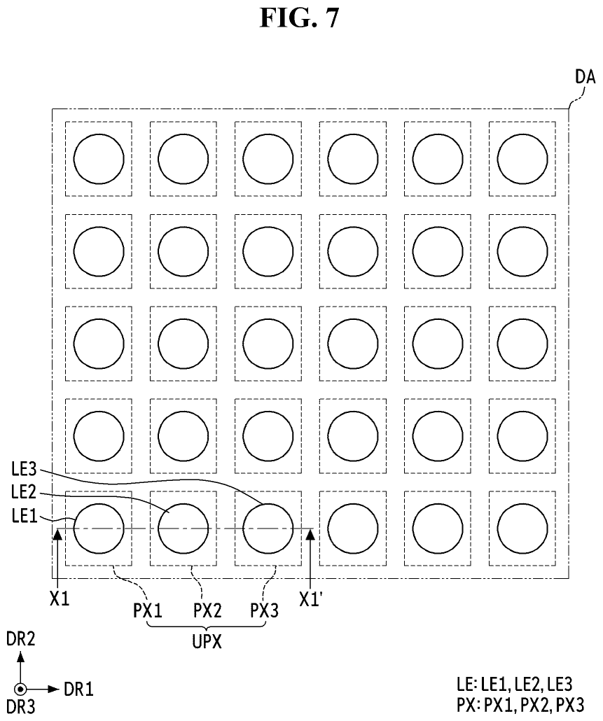

FIG. 7 is a plan view illustrating a display area of a display device according to one or more embodiments. For example, FIG. 7 illustrates a schematic shape of pixels PX that may be located in a portion of the display area DA of FIG. 1. The pixels PX of FIG. 7 may constitute the display 110 of FIG. 2.

Referring to FIGS. 1 to 7, the display device 10 may include a plurality of pixels PX located in the display area DA. For example, the display panel 100 of the display device 10 may include first pixels PX1 (e.g., first color sub-pixels) that emit light of a first color, second pixels PX2 (e.g., second color sub-pixels) that emit light of a second color, and third pixels PX3 (e.g., third color sub-pixels) that emit light of a third color. In one or more embodiments, the first color may be red, the second color may be green, and the third color may be blue, but they are not limited thereto. At least one first pixel PX1, at least one second pixel PX2, and at least one third pixel PX3 adjacent to each other may each constitute a unit pixel UPX. As an example, the first pixel PX1, the second pixel PX2, and the third pixel PX3 sequentially located along the first direction DR1 in the K^{th} (K is a natural number) row of the display area DA may constitute one unit pixel UPX. The number, type, and/or arrangement structure of the pixels PX constituting the unit pixel UPX may vary depending on the embodiments.

The pixels PX may be arranged in the display area DA in a matrix form, a stripe form, or any other form. For example, the arrangement type, location, or size of the pixels PX may be variously changed depending on embodiments.

In one or more embodiments, the pixels PX may have a quadrilateral planar shape, such as a rectangular shape or a rhombic shape, but the embodiments are not limited thereto. For example, the pixels PX may have a quadrilateral shape or another polygonal shape (e.g., a rhombic shape or a hexagonal shape), a circular shape, an elliptical shape, or other planar shapes.

The pixels PX may include the light-emitting elements LE, respectively. For example, the first pixel PX1 may include a first light-emitting element LE1, the second pixel PX2 may include a second light-emitting element LE2, and the third pixel PX3 may include a third light-emitting element LE3. In one or more embodiments, the first light-emitting element LE1, the second light-emitting element LE2, and the third light-emitting element LE3 may emit light of the first color, light of the second color, and light of the third color, respectively. For example, the first light-emitting element LE1, the second light-emitting element LE2, and the third light-emitting element LE3 may emit red light, green light, and blue light, respectively. In one or more other embodiments, the first light-emitting element LE1, the second light-emitting element LE2, and the third light-emitting element LE3 may emit light of the same color (e.g., blue light or white light), and light conversion patterns (e.g., wavelength conversion patterns including quantum dots) and/or color filters to convert or control the color or the wavelength of light emitted from each of the light-emitting elements LE may be located at the upper side of at least one of the first light-emitting element LE1, the second light-emitting element LE2, or the third light-emitting element LE3.

Although FIG. 7 discloses one or more embodiments in which each of the pixels PX includes one light-emitting element LE, the embodiments are not limited thereto. For example, at least one of the first pixel PX1, the second pixel PX2, or the third pixel PX3 may include a plurality of light-emitting elements LE.

In addition, in FIG. 7, only the light-emitting element LE among the components of the pixel PX is illustrated, but the pixel PX may further include an additional component. For example, the pixel PX may further include the pixel circuit PXC connected to each of the light-emitting elements LE. In one or more embodiments, the pixel circuit PXC may include the pixel driver PDU and the switch element SW commonly connected to the first node N1 as illustrated in FIG. 3, and the light-emitting element LE may be electrically connected to the pixel circuit PXC through the first node N1.

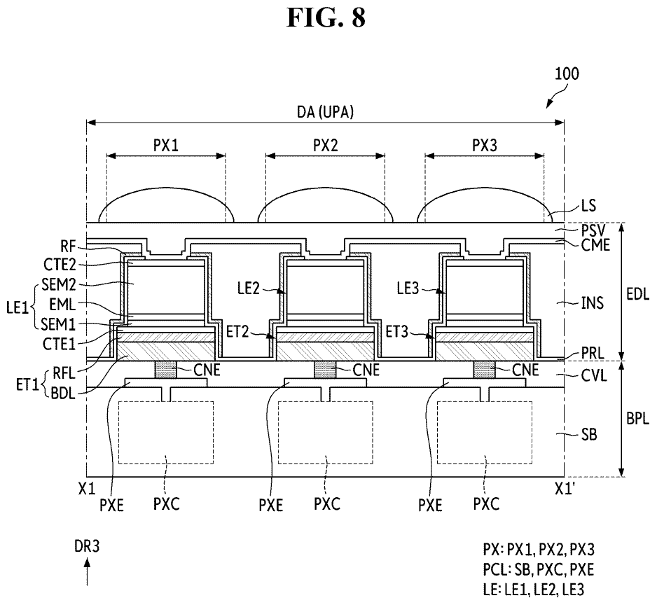

FIG. 8 is a cross-sectional view illustrating a display panel according to one or more embodiments. For example, FIG. 8 shows one or more embodiments of a cross-section of the display panel 100 taken along the X1-X1′ of FIG. 7, which is a schematic cross-section of the first pixel PX1, the second pixel PX2, and the third pixel PX3 located in a unit pixel area UPA of the display area DA.

FIG. 8 illustrates one or more embodiments in which the display device 10 includes the display panel 100 having a light-emitting diode on silicon (LEDoS) structure in which light-emitting diodes are located as the light-emitting elements LE, on a semiconductor circuit substrate PCL formed by a semiconductor process using a silicon wafer. However, the structure or type of the display device or the electronic device to which embodiments may be applied is not limited thereto. For example, the embodiments may be applied to display devices of other types or structures, or may be applied to electronic devices of other types or structures, such as lighting devices.

Referring to FIGS. 1 to 8, the display panel 100 may include the semiconductor circuit substrate PCL (or thin film transistor substrate), connection electrodes CNE and a cover layer CVL (e.g., lower passivation layer) located on (e.g., above) the semiconductor circuit substrate PCL, electrodes ET1, ET2, and ET3 (or “conductive layers”) located on the connection electrodes CNE and the cover layer CVL, and the light-emitting elements LE located on the electrodes ET1, ET2, and ET3.

In one or more embodiments, the display panel 100 may further include at least one of contact electrodes CTE1 or CTE2 located on at least one surface of the light-emitting elements LE, a protective film PRL surrounding the side surfaces of the light-emitting elements LE, a reflective film RF, and an insulating layer INS located around the light-emitting elements LE, or a common electrode CME and a passivation layer PSV (e.g., upper passivation layer) located on the light-emitting elements LE. In one or more embodiments, the display panel 100 may further include optical structures, for example, lenses LS, located on the passivation layer PSV.

The semiconductor circuit substrate PCL may include the display area DA in which the pixel circuits PXC of the pixels PX are formed. The semiconductor circuit substrate PCL may further include the non-display area NDA of FIG. 1. For example, the semiconductor circuit substrate PCL may further include the pads PD positioned in the non-display area NDA. In one or more embodiments, the semiconductor circuit substrate PCL may further include at least one of at least some components of the display driver 120 of FIG. 2 or the test controller 130.

The semiconductor circuit substrate PCL may include the base substrate SB, the pixel circuits PXC located or formed on the base substrate SB, and the pixel electrodes PXE (or contact terminals) electrically connected to the respective pixel circuits PXC. The semiconductor circuit substrate PCL may further include wires electrically connected to the pixels PX.

In one or more embodiments, the semiconductor circuit substrate PCL may be formed through a semiconductor process using a silicon wafer. For example, the base substrate SB may be a silicon wafer. In one or more embodiments, the base substrate SB may be made of monocrystalline silicon.

The pixel circuits PXC may be located in the semiconductor circuit substrate PCL to correspond to the respective pixel areas where the respective pixels PX are located. In one or more embodiments, each of the pixel circuits PXC may include a complementary metal oxide semiconductor (CMOS) circuit formed using a semiconductor process. In one or more embodiments, each of the pixel circuits PXC may include at least one transistor and at least one capacitor formed through a semiconductor process. FIG. 3 illustrates schematic positions of the pixel circuits PXC included in the first pixel PX1, the second pixel PX2, and the third pixel PX3, as an example of elements located in the semiconductor circuit substrate PCL.

As in the embodiments described above, the pixel circuit PXC of each of the first pixel PX1, the second pixel PX2, and the third pixel PX3 may include the pixel driver PDU and the switch element SW, and the pixel driver PDU and the switch element SW may be commonly connected to the pixel electrode PXE of each of the pixels PX. For example, the pixel electrode PXE of FIG. 8 may form the first node N1 of FIG. 3 and may be a contact terminal for electrically connecting the pixel circuit PXC to the light-emitting element LE.

The pixel electrodes PXE may be located on the respective pixel circuits PXC. The pixel electrodes PXE may be connected to the respective pixel circuits PXC. For example, the pixel circuit PXC of each pixel PX may be electrically connected to the pixel electrode PXE of the corresponding pixel PX. The pixel electrode PXE may receive a first voltage VDD (e.g., an anode voltage) from each of the pixel circuits PXC. In one or more embodiments, the pixel electrodes PXE may function as an anode electrode of each of the light-emitting elements LE or the pixels PX. In one or more other embodiments, the display panel 100 may have a common-anode structure, and the pixel electrodes PXE may be connected to the second power line PL2, to which the second voltage VSS is applied, to function as a cathode electrode of each of the light-emitting elements LE or the pixels PX.

In one or more embodiments, the pixel electrodes PXE1 may be formed integrally with the respective pixel circuits PXC. For example, the pixel electrodes PXE may be exposed electrodes that protrude from the top surfaces of the respective pixel circuits PXC.

The pixel electrodes PXE may include at least one conductive material. For example, the pixel electrodes PXE may include, but not limited to, copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof.

The pixel electrodes PXE may be electrically connected to the respective light-emitting elements LE through the respective connection electrodes CNE and the respective electrodes ET1, ET2, and ET3 (e.g., bonding electrodes). For example, the pixel electrode PXE of the first pixel PX1 may be electrically connected to the first light-emitting element LE1 on the first electrode ET1 through the first electrode ET1 and the connection electrode CNE of the first pixel PX1. The pixel electrode PXE of the second pixel PX2 may be electrically connected to the second light-emitting element LE2 on the second electrode ET2 through the second electrode ET2 and the connection electrode CNE of the second pixel PX2. The pixel electrode PXE of the third pixel PX3 may be electrically connected to the third light-emitting element LE3 on the third electrode ET3 through the third electrode ET3 and the connection electrode CNE of the third pixel PX3. In one or more embodiments, the first contact electrodes CTE1 may be located between the electrodes ET1, ET2, and ET3 and the light-emitting elements LE, and the electrodes ET1, ET2, and ET3 may be electrically connected to the respective light-emitting elements LE through the respective first contact electrodes CTE1.

The cover layer CVL may be located on the pixel circuits PXC and the pixel electrodes PXE. The cover layer CVL may cover the semiconductor circuit substrate PCL including the base substrate SB, the pixel circuits PXC, and the pixel electrodes PXE.

The cover layer CVL may include openings (e.g., contact holes or via holes) that partially expose the pixel electrodes PXE. The openings may be filled with the connection electrodes CNE. For example, the cover layer CVL may surround the connection electrodes CNE.

The cover layer CVL includes at least one insulating material, and may be an insulating layer having a single-layer or multilayer structure. In one or more embodiments, the cover layer CVL may include an inorganic insulating material (e.g., silicon oxide (SiOₓ), silicon nitride (SiNₓ), silicon oxynitride (SiOₓN_{y}), aluminum oxide (AlₓO_{y}), titanium oxide (TiₓO_{y}), hafnium oxide (HfOₓ), or other inorganic insulating materials), but is not limited thereto.

The connection electrodes CNE may connect the semiconductor circuit substrate PCL to the electrodes ET1, ET2, and ET3. For example, each of the connection electrodes CNE may be electrically connected between the first electrode ET1, the second electrode ET2, or the third electrode ET3 of each of the pixels PX and the pixel electrode PXE.

In one or more embodiments, the connection electrodes CNE may include a conductive metal. For example, the connection electrodes CNE may include at least one of gold (Au), copper (Cu), tin (Sn), titanium (Ti), aluminum (Al), or silver (Ag), but are not limited thereto.

The semiconductor circuit substrate PCL, the connection electrodes CNE, and the cover layer CVL may constitute a backplane layer BPL of the display panel 100. A light-emitting element layer EDL including the light-emitting elements LE may be located on the backplane layer BPL. In one or more embodiments, the display panel 100 may include the electrodes ET1, ET2, and ET3 located on the backplane layer BPL, and the light-emitting elements LE may be located on the electrodes ET1, ET2, and ET3. The backplane layer BPL and the light-emitting elements LE may be coupled or connected by the electrodes ET1, ET2, and ET3.

The light-emitting element layer EDL may include the electrodes ET1, ET2, and ET3, the light-emitting elements LE, the insulating layer INS, the common electrode CME, and the passivation layer PSV. In one or more embodiments, the light-emitting element layer EDL (or the light-emitting elements LE) may further include the contact electrodes CTE1 and CTE2.

In one or more embodiments, the electrodes ET1, ET2, and ET3 of the first pixel PX1, the second pixel PX2, and the third pixel PX3 may be located in the same layer. For example, the electrodes ET1, ET2, and ET3 may be located on the cover layer CVL.

The electrodes ET1, ET2, and ET3 may be located separately from each other in respective pixel areas in which the pixels PX are located. For example, the first electrode ET1 may be individually located in a first pixel area in which each of the first pixels PX1 is located, the second electrode ET2 may be individually located in a second pixel area in which each of the second pixels PX2 is located, and the third electrode ET3 may be individually located in a third pixel area in which each of the third pixel PX3 is located.

The electrodes ET1, ET2, and ET3 may electrically connect the light-emitting elements LE of the pixels PX to the pixel electrodes PXE, respectively. For example, the first electrode ET1 may electrically connect the pixel electrode PXE of the first pixel PX1 and the first light-emitting element LE1. The second electrode ET2 may electrically connect the pixel electrode PXE of the second pixel PX2 and the second light-emitting element LE2. The third electrode ET3 may electrically connect the pixel electrode PXE of the third pixel PX3 and the third light-emitting element LE3.

The electrodes ET1, ET2, and ET3 may physically and/or electrically couple the backplane layer BPL and the light-emitting elements LE. In one or more embodiments, the electrodes ET1, ET2, and ET3 may be bonding electrodes (or bonding pads) for stably placing or bonding the light-emitting elements LE on the backplane layer BPL. For example, the first electrode ET1 may be a first bonding electrode corresponding to the bonding electrode of the first pixel PX1, the second electrode ET2 may be a second bonding electrode corresponding to the bonding electrode of the second pixel PX2, and the third electrode ET3 may be a third bonding electrode corresponding to the bonding electrode of the third pixel PX3.

However, the types of the electrodes ET1, ET2, and ET3 are not limited thereto, and the types, structures, and/or materials of the electrodes ET1, ET2, and ET3 may vary according to the coupling structure, the coupling method, or the like between the backplane layer BPL and the light-emitting elements LE. Hereinafter, one or more embodiments in which the electrodes ET1, ET2, and ET3 are bonding electrodes is described.

Each of the electrodes ET1, ET2, and ET3 may include a single layer or multiple layers including the bonding layer BDL (also referred to as “bonding metal layer”). For example, each of the electrodes ET1, ET2, and ET3 may include the bonding layer BDL, and a reflective layer RFL located on the bonding layer BDL.

The bonding layer BDL may be located on the backplane layer BPL. For example, the bonding layer BDL may be located on the connection electrode CNE and the cover layer CVL of each of the pixels PX.

In one or more embodiments, the bonding layer BDL may include a conductive material suitable for the bonding process. For example, the bonding layer BDL may include a metal or metal alloy with excellent electrical and thermal conductivity, or may include a transparent conductive material that allows a bonding process. Examples of metals or metal alloys that may be included in the bonding layer BDL include eutectic metals, such as gold (Au)-tin (Sn) alloy, titanium (Ti), zirconium (Zr), nickel (Ni), or chromium (Cr). Examples of transparent conductive materials that may be included in the bonding layer BDL may include indium tin oxide (ITO), zinc oxide (ZnO), or the like. The bonding layer BDL may also be formed of other conductive materials.

In one or more embodiments, the bonding layer BDL may have a thickness sufficient to be appropriately or easily performed with the bonding process. For example, the bonding layer BDL may have a thickness of approximately several hundred nm (e.g., a thickness in a range of approximately 200 nm to approximately 500 nm), but is not limited thereto.

The reflective layer RFL may be located on the bonding layer BDL. In one or more embodiments, the reflective layer RFL may include a conductive material (e.g., metal) with high light reflectivity. For example, the reflective layer RFL may include aluminum (Al) or may include other metals (e.g., molybdenum (Mo), titanium (Ti), copper (Cu), silver (Ag), magnesium (Mg), platinum (Pt), palladium (Pd), gold (Au), nickel (Ni), neodymium (Nd), iridium (Ir), or chromium (Cr)) with high light reflectivity. In one or more other embodiments, the reflective layer RFL may include a plurality of transparent conductive layers that may function as distributed Bragg reflectors (DBR).

In one or more embodiments, the reflective layer RFL may completely cover the bottom surface of each of the light-emitting elements LE. Accordingly, the light that has traveled downward from each of the light-emitting elements LE may be effectively reflected, so that the light efficiency of the light-emitting element LE and the pixel PX including the same may be increased.

In one or more embodiments, each of the electrodes ET1, ET2, and ET3 may further include a barrier layer covering at least one surface of the bonding layer BDL or the reflective layer RFL. For example, each of the electrodes ET1, ET2, and ET3 may further include at least one of a first barrier layer covering a bottom surface of the bonding layer BDL, a second barrier layer covering a top surface of the bonding layer BDL and a bottom surface of the reflective layer RFL, or a third barrier layer covering a top surface of the reflective layer RFL.

The barrier layer may include a material suitable for reducing or preventing diffusion (e.g., reducing or preventing inter-metal diffusion). Additionally, the barrier layer may be formed of a material and/or thickness capable of ensuring conductivity of each of the electrodes ET1, ET2, and ET3. In one or more embodiments, the barrier layer may include a material with a high inter-metal diffusion reduction or prevention effect, such as titanium (Ti), titanium nitride (TiN), nickel (Ni), or other diffusion reduction or prevention materials, and may be formed to have a thickness less than or equal to the thickness of each of the reflective layer RFL and the bonding layer BDL. For example, the barrier layer may be formed of a thin film including a material suitable for reducing or preventing diffusion of the metal included in the bonding layer BDL and/or the reflective layer RFL.

The light-emitting elements LE may be located on the electrodes ET1, ET2, and ET3. In one or more embodiments, the light-emitting elements LE of the first pixel PX1, the second pixel PX2, and the third pixel PX3 may be located in the same layer within the light-emitting element layer EDL. The light-emitting elements LE of the first pixel PX1, the second pixel PX2, and the third pixel PX3 may be substantially concurrently or substantially simultaneously or sequentially located or formed on the respective electrodes ET1, ET2, and ET3. When the light-emitting elements LE of the first pixel PX1, the second pixel PX2, and the third pixel PX3 are located in the same layer, the structure of the display panel 100 may be simplified, and the thickness thereof may be reduced. In one or more embodiments, when the light-emitting elements LE of the first pixel PX1, the second pixel PX2, and the third pixel PX3 are the light-emitting elements LE of the same color or type, the process of forming the light-emitting element layer EDL may be streamlined or simplified.

In one or more embodiments, the first contact electrode CTE1 may be located on each of the electrodes ET1, ET2, and ET3, and the light-emitting element LE of each of the pixels PX may be located on the first contact electrode CTE1. In FIG. 8, the first contact electrode CTE1 is illustrated as a separate component from the light-emitting element LE, but embodiments are not limited thereto. For example, the first contact electrode CTE1 may be regarded as a component included in the light-emitting element LE. The first contact electrode CTE1 may be formed or etched together with the light-emitting element LE, or may be formed or etched separately from the light-emitting element LE.

In one or more other embodiments, the light-emitting element LE or the pixel PX may not include the first contact electrode CTE1. In this case, the light-emitting element LE may be directly located on the first electrode ET1, the second electrode ET2, or the third electrode ET3 of each of the pixels PX.

In FIG. 8, the display panel 100 having a structure in which the electrodes ET1, ET2, and ET3 are located on the backplane layer BPL including the semiconductor circuit substrate PCL and the light-emitting elements LE are coupled to the backplane layer BPL by the electrodes ET1, ET2, and ET3 is illustrated, but the structure of the display panel 100 according to the embodiments is not limited thereto. For example, the light-emitting elements LE may be appropriately located on the backplane layer BPL by utilizing adhesive layers, connection electrodes, and/or wires, or the like without using a bonding method.

The first contact electrode CTE1 may be located on the first electrode ET1, the second electrode ET2, or the third electrode ET3 of each of the pixels PX. The first contact electrode CTE1 may be located on one surface (e.g., bottom surface) of a first semiconductor layer SEM1 included in the light-emitting element LE. The first contact electrode CTE1 may protect the first semiconductor layer SEM1, and may smoothly connect the light-emitting element LE to the bonding electrode BDE.

The first contact electrode CTE1 may include a metal, a metal oxide, or other conductive materials. In one or more embodiments, the first contact electrode CTE1 may include a transparent conductive material (e.g., indium tin oxide (ITO), indium zinc oxide (IZO), or another transparent conductive material), but is not limited thereto.

Each of the light-emitting elements LE may be located on the first contact electrode CTE1 (or the first electrode ET1, the second electrode ET2, or the third electrode ET3 of each of the pixels PX, respectively) of a corresponding pixel PX.

Each of the light-emitting elements LE may include the first semiconductor layer SEM1, the light-emitting layer EML, and the second semiconductor layer SEM2 sequentially located on the first contact electrode CTE1. For example, the first semiconductor layer SEM1, the light-emitting layer EML, and the second semiconductor layer SEM2 may be sequentially located or stacked on the first contact electrode CTE1 along the third direction DR3. The first semiconductor layer SEM1, the light-emitting layer EML, and the second semiconductor layer SEM2 may be formed from a semiconductor thin film layer (semiconductor epitaxial stack) or from epi-layers formed by epitaxial growth on a semiconductor substrate.

In one or more embodiments, the light-emitting elements LE may be formed by etching the semiconductor thin film layer or the epi-layers, which are grown on a semiconductor substrate, on the semiconductor substrate, and the light-emitting elements LE may be located or bonded on the electrodes ET1, ET2, and ET3 by using at least one transfer substrate. In one or more other embodiments, a semiconductor thin film layer or epi-layers grown on the semiconductor substrate may be located or bonded on the backplane layer BPL by a wafer-to-wafer bonding process or the like, and then may be etched to form the light-emitting elements LE. The electrodes ET1, ET2, and ET3 may be etched and separated into individual patterns after the light-emitting elements LE are formed or located on the backplane layer BPL, or may be formed and separated into individual patterns before the light-emitting elements LE are formed or located on the backplane layer BPL.

The first semiconductor layer SEM1 may include a semiconductor material doped with a first conductivity type dopant. For example, the first semiconductor layer SEM1 may be a semiconductor layer of a first conductivity type that includes a nitride-based semiconductor material, a phosphide-based semiconductor material, or another semiconductor material, and that further includes a dopant of a first conductivity type. In one or more embodiments, the first semiconductor layer SEM1 may be a p-type semiconductor layer (e.g., p-GaN) doped with a p-type dopant, such as Mg, Zn, Ca, Se, and Ba, but is not limited thereto.

The light-emitting layer EML may be located on the first semiconductor layer SEM1. For example, the light-emitting layer EML may be located between the first semiconductor layer SEM1 and the second semiconductor layer SEM2. The light-emitting layer EML may emit light by recombination of electron-hole pairs generated in response to an electrical signal applied through the first semiconductor layer SEM1 and the second semiconductor layer SEM2.

The light-emitting layer EML may include a nitride-based semiconductor material, a phosphide-based semiconductor material, or another semiconductor material, and may have a single or multiple quantum well structure. In one or more embodiments, the light-emitting layer EML may have a multiple quantum well structure including a quantum well layer including InGaN and a barrier layer including GaN, AlGaN, or GaAlN, but is not limited thereto. In one or more embodiments, when the light-emitting layer EML includes InGaN, the color of light emitted from the light-emitting layer EML may be adjusted or changed by adjusting the content of indium (In).

The light-emitting layer EML may emit light in a visible light wavelength band, for example, light in a wavelength band of approximately 400 nm to approximately 900 nm. For example, the light-emitting layer EML may emit blue light having a peak wavelength within a range of approximately 440 nm to approximately 480 nm, green light having a peak wavelength within a range of approximately 510 nm to approximately 550 nm, or red light having a peak wavelength within a range of approximately 610 nm to approximately 650 nm. For example, the light-emitting layer EML of the first light-emitting element LE1 may emit red light, the light-emitting layer EML of the second light-emitting element LE2 may emit green light, and the light-emitting layer EML of the third light-emitting element LE3 may emit blue light. However, the embodiments are not limited thereto, and the light-emitting layer EML may emit light of which color or wavelength band is different from the color or the wavelength band described above.

The second semiconductor layer SEM2 may include a semiconductor material doped with a second conductivity type dopant. For example, the second semiconductor layer SEM2 may be a semiconductor layer of a second conductivity type that includes a nitride-based semiconductor material, a phosphide-based semiconductor material, or another semiconductor material, and further includes a dopant of a second conductivity type. In one or more embodiments, the second semiconductor layer SEM2 may be an n-type semiconductor layer (e.g., n-GaN) doped with an n-type dopant, such as Si, Ge, and Sn, but is not limited thereto.

In one or more embodiments, the second contact electrode CTE2 may be located on each of the light-emitting elements LE, and the common electrode CME may be located on the second contact electrode CTE2. For example, the second semiconductor layer SEM2 of the light-emitting element LE may be electrically connected to the common electrode CME through the second contact electrode CTE2.

In FIG. 8, the second contact electrode CTE2 is illustrated as a separate component from the light-emitting element LE, but the embodiments are not limited thereto. For example, the second contact electrode CTE2 may be regarded as a component included in the light-emitting element LE. The second contact electrode CTE2 may be formed or etched together with the light-emitting element LE, or may be formed or etched separately from the light-emitting element LE.

In one or more other embodiments, the light-emitting element LE or the pixel PX may not include the second contact electrode CTE2. In this case, the common electrode CME may be directly connected or in contact with the light-emitting element LE.

The second contact electrode CTE2 may be located on one surface (e.g., top surface) of the second semiconductor layer SEM2. The second contact electrode CTE2 may protect the second semiconductor layer SEM2, and may smoothly connect the light-emitting element LE to the common electrode CME.

The second contact electrode CTE2 may include a metal, a metal oxide, or other conductive materials. In one or more embodiments, the second contact electrode CTE2 may be formed of a transparent electrode layer including a transparent conductive material (e.g., indium tin oxide (ITO), indium zinc oxide (IZO), or another transparent conductive material). Accordingly, light generated in the light-emitting element LE may pass through the second contact electrode CTE2, and may be emitted to the upper side of the light-emitting element LE.

The light-emitting elements LE may be surrounded (e.g., in plan view) by the protective film PRL or the like. For example, each side surface of the light-emitting elements LE may be surrounded by the protective film PRL and the reflective film RF (e.g., in plan view).

The protective film PRL may surround the side surfaces of the light-emitting elements LE. In one or more embodiments, the protective film PRL may further surround the side surface of at least one of the electrodes ET1, ET2, or ET3, the first contact electrode CTE1, or the second contact electrode CTE2. For example, the protective film PRL may be entirely located across the display area DA to surround the side surfaces of the light-emitting elements LE, the electrodes ET1, ET2, and ET3, the first contact electrode CTE1, and the second contact electrode CTE2.

The protective film PRL may include, or define, an opening exposing a portion, for example, a top surface, of each of the light-emitting elements LE or the second contact electrodes CTE2. For example, the protective film PRL may include/define an opening that exposes a portion (e.g., a portion of the top surface) of each of the light-emitting elements LE or the second contact electrode CTE2. In the opened portion of the protective film PRL, the light-emitting element LE or the second contact electrode CTE2 may be connected to the common electrode CME.

The protective film PRL may include at least one insulating material selected from silicon oxide (SiOₓ), silicon nitride (SiNₓ), aluminum oxide (AlₓO_{y}), titanium oxide (TiₓO_{y}), and hafnium oxide (HfOₓ), or another insulating material. The protective film PRL may protect the light-emitting element LE, and may improve the electrical stability of the light-emitting element LE.

The reflective film RF may be located over at least a portion of the protective film PRL. For example, the reflective film RF may be located on a portion of the protective film PRL that surrounds a side surface of each of the light-emitting elements LE.

The reflective film RF may surround a side surface of each of the light-emitting elements LE. For example, in plan view, the reflective film RF may surround the light-emitting elements LE.

The reflective film RF may reflect and recycle light generated from each of the light-emitting elements LE and directed in a lateral direction, or the like. The light emission efficiency (e.g., a proportion of light emitted from the upper side of the light-emitting element LE) of each of the light-emitting elements LE may be increased by the reflective film RF.

In one or more embodiments, the reflective film RF may include a metal with high reflectivity, such as aluminum (Al). In one or more other embodiments, the reflective film RF may include a distributed Bragg reflector. For example, the reflective film RF may include at least one pair (e.g., two or more pairs) of a first layer and a second layer having different refractive indices, and located alternately or sequentially. One of the first layer and the second layer may be a low refractive layer, and the other may be a high refractive layer with a higher refractive index than the low refractive layer. The first layer and the second layer may be formed of an inorganic film, for example, silicon nitride (SiNₓ), silicon oxynitride (SiON), silicon oxide (SiOₓ), titanium oxide (TiₓO_{y}), aluminum oxide (AlₓO_{y}), or the like.

The insulating layer INS may be located on the protective film PRL and the reflective film RF. The insulating layer INS may be located around the light-emitting elements LE to surround each of the light-emitting elements LE. For example, the insulating layer INS may also be located between the light-emitting elements LE.

In one or more embodiments, the insulating layer INS may be formed to have a height that is higher than or equal to the height of the light-emitting elements LE, and may be opened at the upper side of each of the light-emitting elements LE. For example, the insulating layer INS may include openings that expose a portion of the top surface of each of the light-emitting elements LE.

The insulating layer INS may include a single layer or multiple layers including at least one insulating material. For example, the insulating layer INS may include silicon oxide (SiOₓ), silicon nitride (SiNₓ), silicon oxynitride (SiOₓN_{y}), aluminum oxide (AlₓO_{y}), titanium oxide (TiₓO_{y}), hafnium oxide (HfOₓ), or other inorganic insulating materials.

The common electrode CME may be located on the light-emitting elements LE, the second contact electrodes CTE2, and the insulating layer INS.

In one or more embodiments, the common electrode CME may be entirely located in the display area DA. For example, the common electrode CME may be a common layer shared by the light-emitting elements LE of the display area DA, and the pixels PX including the same.

The common electrode CME may be electrically connected to the light-emitting elements LE. For example, openings may be formed in the protective film PRL and the insulating layer INS at the upper side of each of the light-emitting elements LE, and within the openings, the common electrode CME may be connected to the second contact electrodes CTE2 (or the light-emitting elements LE).

In one or more embodiments, the common electrode CME may be electrically connected to the second contact electrodes CTE2, and may be electrically connected to the second semiconductor layer SEM2 of the light-emitting elements LE through the second contact electrodes CTE2. In one or more other embodiments, the pixels PX may not include the second contact electrodes CTE2, and the common electrode CME may be in direct contact with the top surface of each of the light-emitting elements LE, and may be electrically connected to the second semiconductor layer SEM2 of the light-emitting elements LE.

In one or more embodiments, the common electrode CME may be electrically connected to a power line formed in the backplane layer BPL, either inside and/or outside the display area DA. For example, the common electrode CME may be electrically connected to the power line, for example, the second power line PL2 of FIG. 3, formed in the backplane layer BPL in the peripheral area PHA immediately adjacent to the display area DA. Accordingly, the common electrode CME may receive the second voltage VSS (e.g., a common voltage or a cathode voltage) from the second power line PL2. In one or more embodiments, the common electrode CME may function as the cathode electrode of the light-emitting elements LE or the pixels PX. In one or more other embodiments, the display panel 100 has a common-anode structure, and the common electrode CME may be connected to the first power line PL1, to which the first voltage VDD is applied, to function as the anode electrode of each of the light-emitting elements LE or the pixels PX.

The common electrode CME may include a transparent conductive material capable of transmitting light. For example, the common electrode CME may be made of indium tin oxide (ITO), indium zinc oxide (IZO), or other transparent conductive materials.

The passivation layer PSV may be located on the common electrode CME. In one or more embodiments, the passivation layer PSV may be located entirely on the display area DA to cover the common electrode CME.

In one or more embodiments, the top surface of the passivation layer PSV may be substantially flat. For example, the passivation layer PSV may be formed of a material and/or thickness suitable to have a substantially flat top surface, or may be planarized by a planarization process performed after film formation.

The passivation layer PSV includes at least one insulating material and may have a single-layer or multilayer structure. In one or more embodiments, the passivation layer PSV may include an inorganic insulating material (e.g., silicon oxide (SiOₓ), silicon nitride (SiNₓ), silicon oxynitride (SiOₓN_{y}), aluminum oxide (AlₓO_{y}), titanium oxide (TiₓO_{y}), hafnium oxide (HfOₓ), or other inorganic insulating materials), but is not limited thereto.

A lens LS may be located on the passivation layer PSV. For example, the lenses LS respectively overlapping the light-emitting elements LE may be located on the passivation layer PSV. In one or more embodiments, each of the lenses LS may have a size corresponding to the emission area of each of the pixels PX, and may completely overlap the light-emitting element LE located in each of the pixels PX. For example, the lens LS may be a microlens corresponding to the size of each of the light-emitting elements LE. In one or more embodiments, each of the lenses LS may have a size that is larger than each of the light-emitting elements LE in plan view, and may cover the light-emitting element LE and the periphery of the light-emitting element LE.

In one or more embodiments, the lens LS may be a microlens in the form of a convex lens provided at the upper side of the light-emitting elements LE, but the type, shape, and/or size of the lens LS is not limited thereto. By arranging the lens LS at the upper side of the light-emitting elements LE, the light emission characteristics of the pixels PX may be adjusted or improved.

The lens LS may be formed of a transparent material, such that light incident from the light-emitting elements LE may be transmitted. As an example, the lens LS may be formed of glass, plastic, ceramic, or other materials, and may be formed of an optical material with a high refractive index.

In one or more embodiments, the display panel 100 or the display device 10 including the same may further include an additional component. For example, the display panel 100 or the display device 10 including the same may further include a light conversion layer or a color filter, or the like, located at the upper side of the pixels PX (or the light-emitting elements LE).

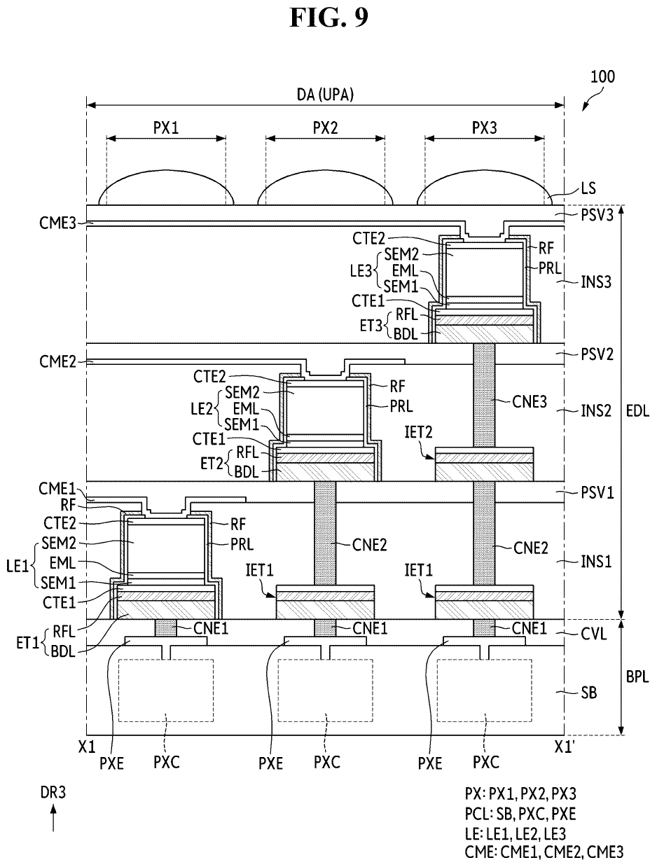

FIG. 9 is a cross-sectional view illustrating a display panel according to one or more embodiments. For example, FIG. 9 illustrates one or more embodiments of a cross-section of the display panel 100 taken along the line X1-X1′ of FIG. 7. FIG. 9 illustrates one or more embodiments different from the one or more embodiments corresponding to FIG. 8 with respect to the light-emitting element layer EDL.

Referring to FIG. 9, the light-emitting elements LE of the first pixel PX1, the second pixel PX2, and the third pixel PX3 may be located in different layers within the light-emitting element layer EDL. In this case, the light-emitting elements LE of the first pixel PX1, the second pixel PX2, and the third pixel PX3 may be sequentially located or formed on the respective electrodes ET1, ET2, and ET3. When the light-emitting elements LE of the first pixel PX1, the second pixel PX2, and the third pixel PX3 are located in different layers, the light-emitting elements LE of different colors or types may be more suitably located or bonded on the backplane layer BPL.

In one or more embodiments, the light-emitting element layer EDL may include a first light-emitting element layer, a second light-emitting element layer, and a third light-emitting element layer sequentially located or stacked on the backplane layer BPL. The first light-emitting element layer may include the first light-emitting element LE1 for each of the first pixels PX1 located in the display area DA, the second light-emitting element layer may include the second light-emitting element LE2 for each of the second pixels PX2 located in the display area DA, and the third light-emitting element layer may include the third light-emitting element LE3 for each of the third pixels PX3 located in the display area DA.

In one or more embodiments, the first light-emitting element LE1, the second light-emitting element LE2, and the third light-emitting element LE3 may be connected to the respective pixel circuits PXC through the first connection electrodes CNE1 located within the backplane layer BPL and penetrating the cover layer CVL. The first connection electrodes CNE1 of FIG. 9 may have a configuration corresponding to the connection electrodes CNE of FIG. 8.

The first light-emitting element layer may include the first electrode ET1 located on the backplane layer BPL, and the first light-emitting element LE1, a first common electrode CME1, and a first passivation layer PSV1 sequentially located on the first electrode ET1. In addition, the first light-emitting element layer may further include the first insulating layer INS1 located between the backplane layer BPL and the first passivation layer PSV1 and located in the periphery of the first light-emitting element LE1, and also may include electrodes (e.g., the first electrode ET1, first intermediate electrodes IET1, and second connection electrodes CNE2) located in the first light-emitting element layer. Each of the first electrode ET1, the first light-emitting element LE1, the first insulating layer INS1, and the first passivation layer PSV1 of FIG. 9 may include materials described as materials of the first electrode ET1, the first light-emitting element LE1, the insulating layer INS, and the passivation layer PSV of FIG. 8, but the present disclosure is not limited thereto. In one or more embodiments, the first light-emitting element layer may further include the contact electrodes CTE1 and CTE2 located on at least one of a bottom surface or a top surface of the first light-emitting element LE1, and the protective film PRL and the reflective film RF covering a side surface of the first light-emitting element LE1.

In one or more embodiments, the first light-emitting element layer may further include the first intermediate electrodes IET1 and the second connection electrodes CNE2 located in the second pixel PX2 and the third pixel PX3. The first intermediate electrode IET1 and the second connection electrode CNE2 of the second pixel PX2 may electrically connect the first connection electrode CNE1 and the second electrode ET2 of the second pixel PX2. The first intermediate electrode IET1 and the second connection electrode CNE2 of the third pixel PX3 may electrically connect the first connection electrode CNE1 and the second electrode ET2 of the third pixel PX3.

In one or more embodiments, the first intermediate electrodes IET1 may include a conductive material included in the first electrode ET1 and/or the first contact electrode CTE1 of the first pixel PX1, and may be concurrently or substantially simultaneously formed with the first electrode ET1 and/or the first contact electrode CTE1 of the first pixel PX1. For example, each of the first intermediate electrodes IET1 may include multiple layers including lower conductive layers respectively including the same conductive material as the bonding layer BDL and the reflective layer RFL of the first electrode ET1, and an upper conductive layer located on the lower conductive layers and including the same conductive material as the first contact electrode CTE1 of the first pixel PX1. However, the material or structure of the first intermediate electrodes IET1 may vary according to embodiments.

The second connection electrodes CNE2 may penetrate the first insulating layer INS1 and the first passivation layer PSV1. The second connection electrodes CNE2 may electrically connect the first intermediate electrodes IET1 of the second pixel PX2 and the third pixel PX3 to the second electrode ET2 and the third electrode ET3, respectively. When the first intermediate electrodes IET1 are omitted, the second connection electrodes CNE2 may electrically connect the first connection electrodes CNE1 of the second pixel PX2 and the third pixel PX3 to the second electrode ET2 and the third electrode ET3, respectively. The second connection electrodes CNE2 may include a conductive material described as the material of the connection electrodes CNE of FIG. 8, but are not limited thereto.

The first common electrode CME1 may be located on the first insulating layer INS1, and may be electrically connected to the first light-emitting element LE1 at an opened portion of the first insulating layer INS1. The first common electrode CME1 may not be located in, or may be omitted from, the second pixel area and the third pixel area in which the second pixel PX2 and the third pixel PX3 are located, or may be opened within the second pixel area and the third pixel area. For example, the first common electrode CME1 may be individually located in the first pixel area in which each of the first pixels PX1 is located, or may be entirely located in the display area DA, but may be opened in at least a portion of the second pixel area and the third pixel area to be insulated from the second connection electrodes CNE2.

The second light-emitting element layer may include the second electrode ET2 located on the first passivation layer PSV1, and the second light-emitting element LE2, a second common electrode CME2, and a second passivation layer PSV2 sequentially located on the second electrode ET2. In addition, the second light-emitting element layer may further include the second insulating layer INS2 located between the first passivation layer PSV1 and the second passivation layer PSV2 and located in the periphery of the second light-emitting element LE2 and electrodes (e.g., the second electrode ET2, a second intermediate electrode IET2, and a third connection electrode CNE3) located in the third light-emitting element layer. Each of the second electrode ET2, the second light-emitting element LE2, the second insulating layer INS2, and the second passivation layer PSV2 of FIG. 9 may respectively include materials described as materials of the second electrode ET2, the second light-emitting element LE2, the insulating layer INS, and the passivation layer PSV of FIG. 8, but the present disclosure is not limited thereto. In one or more embodiments, the second light-emitting element layer may further include the contact electrodes CTE1 and CTE2 located on at least one of a bottom surface or a top surface of the second light-emitting element LE2, and the protective film PRL and the reflective film RF covering a side surface of the second light-emitting element LE2.

In one or more embodiments, the second light-emitting element layer may further include the second intermediate electrode IET2 and the third connection electrode CNE3 located in the third pixel PX3. The second intermediate electrode IET2 and the third connection electrode CNE3 of the third pixel PX3 may electrically connect the second connection electrode CNE2 and the third electrode ET3 of the third pixel PX3.

In one or more embodiments, the second intermediate electrode IET2 may include a conductive material included in the second electrode ET2 and/or the first contact electrode CTE1 of the second pixel PX2, and may be concurrently or substantially simultaneously formed with the second electrode ET2 and/or the first contact electrode CTE1 of the second pixel PX2. For example, the second intermediate electrode IET2 may include multiple layers including lower conductive layers respectively including the same conductive material as the bonding layer BDL and the reflective layer RFL of the second electrode ET2, and an upper conductive layer located on the lower conductive layers and including the same conductive material as the first contact electrode CTE1 of the second pixel PX2. However, the material or structure of the second intermediate electrode IET2 may vary according to embodiments.

The third connection electrode CNE3 may penetrate the second insulating layer INS2 and the second passivation layer PSV2. The third connection electrode CNE3 may electrically connect the second intermediate electrode IET2 and the second connection electrode CNE2 of the third pixel PX3 to the third electrode ET3. When the second intermediate electrode IET2 is omitted, the third connection electrode CNE3 may electrically connect the second connection electrode CNE2 of the third pixel PX3 to the third electrode ET3. The third connection electrode CNE3 may include a conductive material described as the material of the connection electrodes CNE of FIG. 8, but is not limited thereto.

The second common electrode CME2 may be located on the second insulating layer INS2, and may be electrically connected to the second light-emitting element LE2 at an opened portion of the second insulating layer INS2. The second common electrode CME2 may be insulated from the third connection electrode CNE3 by not being located in the third pixel area, or by being opened within the third pixel area.

The third light-emitting element layer may include the third electrode ET3 located on the second passivation layer PSV2, and the third light-emitting element LE3, a third common electrode CME3, and a third passivation layer PSV3 sequentially located on the third electrode ET3. Additionally, the third light-emitting element layer may further include a third insulating layer INS3 located between the second passivation layer PSV2 and the third passivation layer PSV3, and located in the periphery of the third light-emitting element LE3 and the third electrode ET3. The third electrode ET3, the third light-emitting element LE3, the third insulating layer INS3, and the third passivation layer PSV3 of FIG. 9 may respectively include materials described as materials of the third electrode ET3, the third light-emitting element LE3, the insulating layer INS, and the passivation layer PSV of FIG. 8, but are not limited thereto. In one or more embodiments, the third light-emitting element layer may further include the contact electrodes CTE1 and CTE2 located on at least one of a bottom surface or a top surface of the third light-emitting element LE3, and the protective film PRL and the reflective film RF covering a side surface of the third light-emitting element LE3.

The third common electrode CME3 may be located in at least the third pixel area. For example, the third common electrode CME3 may be entirely formed in the display area DA.

The first common electrode CME1, the second common electrode CME2, and the third common electrode CME3 may be electrically connected to power lines (e.g., the second power line PL2) formed in the backplane layer BPL inside the display area DA (e.g., between the pixels PX) and/or outside the display area DA (e.g., in the peripheral area PHA). In one or more embodiments, the first common electrode CME1, the second common electrode CME2, and the third common electrode CME3 may form one common electrode CME. In one or more embodiments, each of the first common electrode CME1, the second common electrode CME2, and the third common electrode CME3 may include a conductive material described as the material of the common electrode CME of FIG. 8, but is not limited thereto.

The display device 10 according to embodiments may include the display panel 100 of various structures, including the display panel 100 according to the embodiments of FIGS. 8 and 9. In embodiments, each of the pixel circuits PXC located or formed within the backplane layer BPL of the display panel 100 may include the pixel driver PDU and the switch element SW commonly connected to the pixel electrode PXE. For example, the pixel circuit PXC of each of the first pixel PX1, the second pixel PX2, and the third pixel PX3 may include the pixel driver PDU and the switch element SW commonly connected to each of the pixel electrodes PXE. Additionally, the light-emitting element LE of each of the first pixel PX1, the second pixel PX2, and the third pixel PX3 may be commonly connected to the pixel driver PDU and the switch element SW of the pixel PX through each of the pixel electrodes PXE.

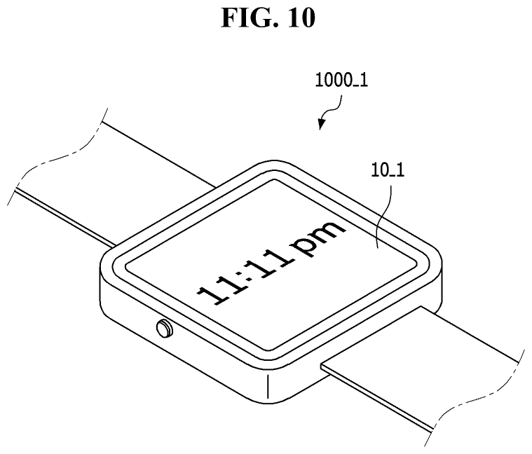

FIG. 10 is a diagram illustrating a smart watch including a display device according to one or more embodiments.

Referring to FIG. 10, a display device 10_1 according to one or more embodiments may be applied to a smart watch 1000_1 that is one of the smart devices.

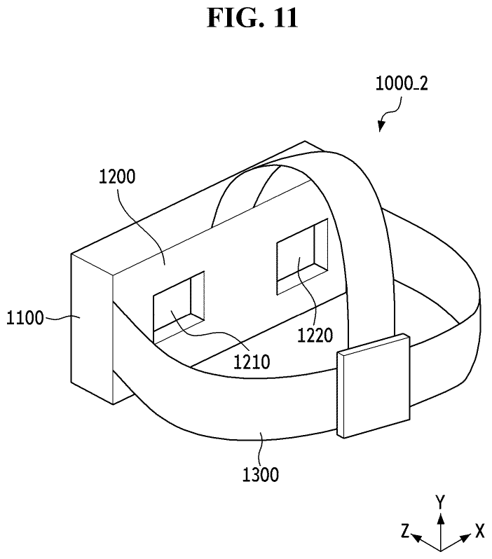

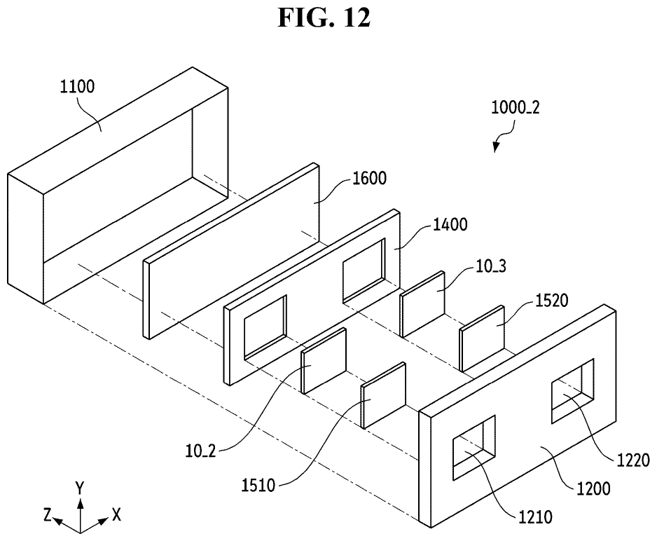

FIGS. 11 and 12 illustrate a head-mounted display including a display device according to one or more embodiments.

Referring to FIGS. 11 and 12, a head-mounted display 1000_2 according to one or more embodiments may be a virtual reality device. The head-mounted display 1000_2 includes a first display device 10_2, a second display device 10_3, a display device housing 1100, a housing cover 1200, a first eyepiece 1210, a second eyepiece 1220, a head-mounted band 1300, a middle frame 1400, a first optical member 1510, a second optical member 1520, and a control circuit board 1600.

The first display device 10_2 provides an image to the user's left eye, and the second display device 10_3 provides an image to the user's right eye.

The first optical member 1510 may be located between the first display device 10_2 and the first eyepiece 1210. The second optical member 1520 may be located between the second display device 10_3 and the second eyepiece 1220. Each of the first optical member 1510 and the second optical member 1520 may include at least one convex lens.

The middle frame 1400 may be located between the first display device 10_2 and the control circuit board 1600, and between the second display device 10_3 and the control circuit board 1600. The middle frame 1400 serves to support and fix the first display device 10_2, the second display device 10_3, and the control circuit board 1600.

The control circuit board 1600 may be located between the middle frame 1400 and the display device housing 1100. The control circuit board 1600 may be connected to the first display device 10_2 and the second display device 10_3 through the connector. The control circuit board 1600 may convert an image source inputted from the outside into video data, and may transmit the video data to the first display device 10_2 and the second display device 10_3 through the connector.

The control circuit board 1600 may transmit the video data corresponding to a left-eye image optimized for the user's left eye to the first display device 10_2, and may transmit the video data corresponding to a right-eye image optimized for the user's right eye to the second display device 10_3. Alternatively, the control circuit board 1600 may transmit the same video data to the first display device 10_2 and the second display device 10_3.

The display device housing 1100 serves to accommodate the first display device 10_2, the second display device 10_3, the middle frame 1400, the first optical member 1510, the second optical member 1520, and the control circuit board 1600. The housing cover 1200 is located to cover one open surface of the display device housing 1100. The housing cover 1200 may include the first eyepiece 1210 at which the user's left eye is located and the second eyepiece 1220 at which the user's right eye is located. FIGS. 11 and 12 illustrate that the first eyepiece 1210 and the second eyepiece 1220 are located separately, but the present disclosure is not limited thereto. The first eyepiece 1210 and the second eyepiece 1220 may be combined into one.

The first eyepiece 1210 may be aligned with the first display device 10_2 and the first optical member 1510, and the second eyepiece 1220 may be aligned with the second display device 10_3 and the second optical member 1520. Therefore, the user may view, through the first eyepiece 1210, the image of the first display device 10_2 magnified as a virtual image by the first optical member 1510, and may view, through the second eyepiece 1220, the image of the second display device 10_3 magnified as a virtual image by the second optical member 1520.

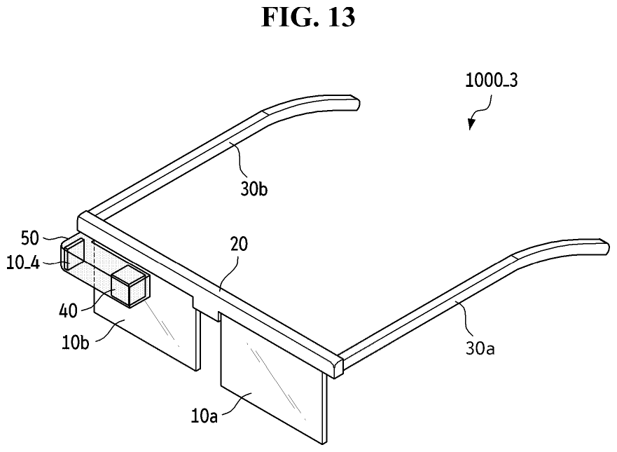

The head-mounted band 1300 serves to secure the display device housing 1100 to the user's head such that the first eyepiece 1210 and the second eyepiece 1220 of the housing cover 1200 remain located on the user's left and right eyes, respectively. When the display device housing 1100 is implemented to be lightweight and compact, the head-mounted display 1000_2 may be provided with, as shown in FIG. 13, an eyeglass frame instead of the head-mounted band 1300.

In addition, the head-mounted display 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi® module, or a Bluetooth® module (Wi-Fi® being a registered trademark of the non-profit Wi-Fi Alliance, and Bluetooth® being a registered trademark of Bluetooth Sig, Inc., Kirkland, WA).

FIG. 13 illustrates a head-mounted display including a display device according to one or more embodiments.

Referring to FIG. 13, a head-mounted display 1000_3 according to one or more embodiments may be a glasses-type device. The head-mounted display 1000_3 according to one or more embodiments may include the display device 10_4, a left eye lens 10a, a right eye lens 10b, a support frame 20, temples 30a and 30b, a reflection member 40, and a display device housing 50.

FIG. 13 illustrates that the head-mounted display 1000_3 is an eyeglasses-type display device including eyeglass frame legs 30a and 30b, but the embodiments are not limited thereto. For example, the head-mounted display 1000_3 may be applied in various forms to other electronic devices.

The display device housing 50 may include the display device 10_4 and the reflection member 40 (or an optical path changing member). An image displayed on the display device 10_4 may be reflected by the reflection member 40, and may be provided to the user's right eye through the right eye lens 10b. As a result, the user may view an augmented reality image, through the right eye, in which a virtual image displayed on the display device 10_4 and a real image seen through the right eye lens 10b are combined. In one or more embodiments, the display device housing 50 may further include an optical member located between the display device 10_4 and the reflection member 40. The image displayed on the display device 10_4 may be magnified by the optical member, and may be provided to the user's right eye through the right eye lens 10b after the optical path thereof is changed by the reflection member 40.

FIG. 13 illustrates that the display device housing 50 is located at the end of the right side of a support frame 20, but the present specification is not limited thereto. For example, the display device housing 50 may be located at the left end of the support frame 20, and in this case, the image displayed on the display device 10_4 may be reflected by the reflection member 40, and may be provided to a user's left eye through the left eye lens 10a. As a result, the user may view the image displayed on the display device 10_4 with the left eye. Alternatively, the display device housing 50 may be located at both the left end and the right end of the support frame 20, in which case the user can view the image displayed on the display device 10_4 through both the left eye and the right eye.

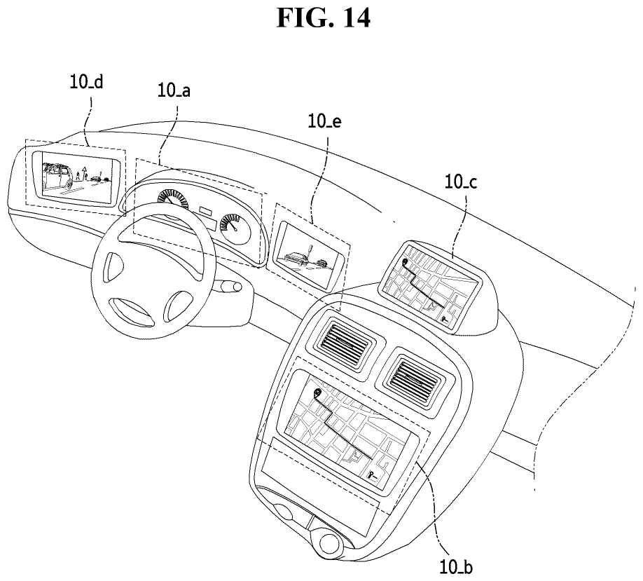

FIG. 14 is a diagram illustrating a dashboard of an automobile and a center fascia including display devices according to one or more embodiments. FIG. 14 illustrates a vehicle to which display devices 10_a, 10_b, 10_c, 10_d, and 10_e according to one or more embodiments are applied.

Referring to FIG. 14, the display devices 10_a, 10_b, and 10_c according to one or more embodiments may be applied to the dashboard of the automobile, the center fascia of the automobile, or the center information display (CID) of the dashboard of the automobile. Further, the display devices 10_d, and 10_e according to one or more embodiments may be applied to a room mirror display instead of side mirrors of the automobile.

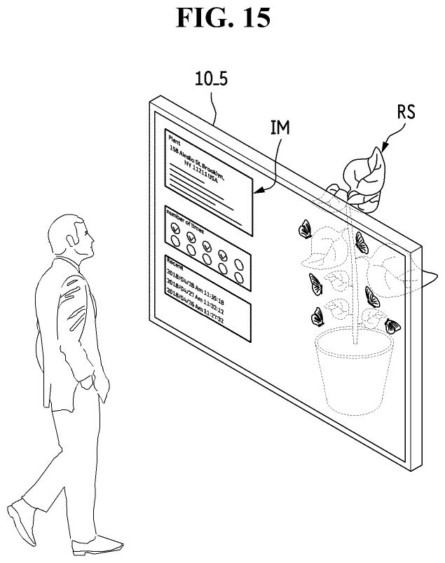

FIG. 15 is a diagram illustrating a transparent display device including a display device according to one or more embodiments.

Referring to FIG. 15, the display device 10_5 according to one or more embodiments may be applied to the transparent display device. The transparent display device may display an image IM, and also may transmit light. Thus, a user located on the front side of the transparent display device can view an object RS or a background on the rear side of the transparent display device as well as the image IM displayed on the display device 10_5. When the display device 10_5 is applied to the transparent display device, the substrate of the display device 10_5 may include a light transmitting portion capable of transmitting light or may be made of a material capable of transmitting light.

In concluding the detailed description, those skilled in the art will appreciate that many variations and modifications can be made to the embodiments without substantially departing from the aspects of the present disclosure. Therefore, the disclosed embodiments are used in a generic and descriptive sense only and not for purposes of limitation.

What is claimed is:

1. A display device comprising:
a pixel in a display area, and comprising:
a pixel driver connected between a first power line, which is configured to receive a first voltage, and a first node, and comprising a driving transistor;
a light-emitting element connected between a second power line, which is configured to receive a second voltage that is different from the first voltage, and the first node; and
a switch element connected between the first node and a current detection terminal, and configured to be turned on in response to a test control signal supplied during a test period.

2. The display device of claim 1, wherein the pixel driver comprises transistors connected in series between the first power line and the first node, and comprising the driving transistor, and
wherein the switch element is directly connected to the first node.

3. The display device of claim 1, further comprising:
a backplane layer comprising the pixel driver, the switch element, and a pixel electrode connected to the pixel driver and to the switch element at the first node; and
a light-emitting element layer above the backplane layer, and comprising the light-emitting element.

4. The display device of claim 3, wherein the light-emitting element is commonly connected to the pixel driver and to the switch element through the pixel electrode.

5. The display device of claim 3, wherein the display device comprises a first pixel, a second pixel, and a third pixel, which comprise respective pixel drivers, respective light-emitting elements, and respective switch elements, and respectively emit light of a first color, light of a second color, and light of a third color.

6. The display device of claim 5, wherein the light-emitting elements of the first pixel, the second pixel, and the third pixel are at a same layer within the light-emitting element layer.

7. The display device of claim 5, wherein the light-emitting elements of the first pixel, the second pixel, and the third pixel are at different respective layers within the light-emitting element layer.

8. The display device of claim 1, further comprising:
a display driver configured to supply driving signals to the pixel during a display period, which is for displaying an image corresponding to input image data in the display area, and during the test period; and
a test controller configured to supply the test control signal to the switch element during the test period.

9. The display device of claim 8, wherein the display driver comprises:
a data driver configured to supply digital data, which corresponds to input image data or test image data, to the pixel during the display period and the test period; and
a clock generator configured to supply a clock signal to the pixel during the display period and the test period.

10. The display device of claim 9, wherein the pixel driver comprises a pulse generator connected to a gate electrode of the driving transistor to generate a pulse signal corresponding to the digital data, and
wherein the driving transistor is configured to supply a current to the first node in response to the pulse signal.

11. The display device of claim 10, wherein the display driver further comprises a current controller configured to supply a bias signal to the pixel.

12. The display device of claim 11, wherein the pixel driver further comprises a bias transistor connected in series with the driving transistor between the first power line and the first node, and configured to adjust the current in response to the bias signal.

13. The display device of claim 12, wherein the bias transistor comprises:
a first bias transistor connected between the driving transistor and the first node, and configured to control the current in response to a first bias signal supplied from the current controller; and
a second bias transistor connected between the first bias transistor and the first node, and configured to control the current in response to a second bias signal supplied from the current controller.

14. The display device of claim 13, further comprising pixels in the display area, and comprising the pixel, a first pixel configured to emit light of a first color, a second pixel configured to emit light of a second color, and a third pixel configured to emit light of a third color.

15. The display device of claim 14, wherein the current controller is configured to supply a same first bias signal to respective first bias transistors of the first pixel, the second pixel, and the third pixel, and is configured to supply different respective second bias signals to respective second bias transistors of the first pixel, the second pixel, and the third pixel.

16. A method of testing a display device comprising a pixel comprising a pixel driver, a light-emitting element, and a switch element commonly connected to a first node, the method comprising:
supplying driving signals and a test control signal to the pixel during a test period in which a test mode is executed; and
detecting a current flowing through the first node through the switch element turned on by the test control signal.

17. The method of claim 16, wherein the switch element is directly connected to the first node, and
wherein the current flowing through the first node is directly detected through the switch element.

18. The method of claim 16, further comprising determining whether the pixel is defective based on the current.

19. An electronic device comprising a display device comprising:
a pixel in a display area, and comprising:
a pixel driver connected between a first power line, which is configured to receive a first voltage, and a first node, and comprising a driving transistor;
a light-emitting element connected between a second power line, which is configured to receive a second voltage that is different from the first voltage, and the first node; and
a switch element connected between the first node and a current detection terminal, and configured to be turned on in response to a test control signal supplied during a test period.

20. The electronic device of claim 19, wherein the electronic device comprises a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, a head-mounted display (HMD), a virtual reality (VR) device, or an augmented reality (AR) device.
